(19) United States
(12) Patent Application Publication
(10) Pub. No.: US 2025/0359467 A1
(43) Pub. Date: Nov. 20, 2025

(54) DISPLAY DEVICE AND METHOD OF MANUFACTURING THE SAME

(71) Applicant: Samsung Display Co., LTD., Yongin-si (KR)

(72) Inventors: Nam Jin KIM, Yongin-si (KR); Yeon Ju SEO, Yongin-si (KR); Won Jang KI, Yongin-si (KR); Seong Sik AHN, Yongin-si (KR)

(73) Assignee: Samsung Display Co., LTD., Yongin-si (KR)

(21) Appl. No.: 18/962,267

(22) Filed: Nov. 27, 2024

(30) Foreign Application Priority Data
May 14, 2024 (KR) 10-2024-0062922

(51) Int. Cl. H10K 59/80; H10K 59/40

(52) U.S. Cl. CPC H10K 59/873; H10K 59/40; H10K 59/8793

(57) ABSTRACT

A display device includes a display area and a non-display area. The display device includes a base layer that includes a first base, a first barrier layer on the first base, a second base on the first barrier layer, and a second barrier layer on the second base; a light emitting element disposed on the base layer in the display area; and an upper organic layer disposed over the display area and the non-display area. Each of the first base and the second base includes an organic material. Each of the first barrier layer and the second barrier layer includes an inorganic material. The non-display area includes an organic contact area, and the second barrier layer exposes the second base in the organic contact area. The upper organic layer and the second base contact each other in the organic contact area.

### CROSS-REFERENCE TO RELATED APPLICATION

This application claims priority to and benefits of Korean Patent Application No. 10-2024-0062922 under 35 U.S.C. § 119, filed in the Korean Intellectual Property Office on May 14, 2024, the entire contents of which are incorporated herein by reference.

### BACKGROUND

### 1. Technical Field

The disclosure relates to a display device and a method of manufacturing the display device.

### 2. Description of the Related Art

In recent years, as interest in information display has increased, research and development on display devices have been continuously conducted.

A display device needs to have robust characteristics against the external environment. For example, the display device requires a structure that prevents risks associated with impurities penetration, such as moisture ingress or stress generation.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a display device having robust characteristics against the external environment, and a method of manufacturing the display device.

The disclosure provides a display device in which the risk of moisture penetration and stress may be reduced, and a method of manufacturing the display device.

The disclosure provides a display device in which the risk of delamination of inorganic layers included in the display device may be reduced, and a method of manufacturing the display device.

According to embodiments of the disclosure, a display device including a display area and a non-display area may include a base layer including a first base, a first barrier layer on the first base, a second base on the first barrier layer, and a second barrier layer on the second base; a light emitting element disposed on the base layer in the display area; and an upper organic layer disposed over the display area and the non-display area. Each of the first base and the second base may include an organic material. Each of the first barrier layer and the second barrier layer may include an inorganic material. The non-display area may include an organic contact area, and the second barrier layer may expose the second base in the organic contact area. The upper organic layer and the second base may contact each other in the organic contact area.

According to an embodiment, the display device may further include a buffer layer disposed on the second barrier layer, extending over the display area and the non-display area; an active layer disposed on the buffer layer in the display area; a gate insulating layer disposed on the buffer layer, extending over the display area and the non-display area, and covering the active layer; a gate conductive layer including at least a portion disposed on the gate insulating layer in the display area; an interlayer insulating layer disposed on the gate insulating layer, extending over the display area and the non-display area, and covering the gate conductive layer; and a first inorganic insulating layer, extending over the display area and the non-display area, and covering the light emitting element. The second barrier layer may include a barrier end portion in the non-display area. The buffer layer may include a buffer end portion in the non-display area. The gate insulating layer may include a gate insulating end portion in the non-display area. The interlayer insulating layer may include an interlayer insulating end portion in the non-display area. The first inorganic insulating layer may include a first inorganic insulating end portion in the non-display area.

According to an embodiment, the buffer layer and the active layer may contact each other. The buffer layer may expose the second base in the non-display area and may not expose the second base in the display area.

According to an embodiment, the first inorganic insulating end portion may be disposed between the buffer end portion and the interlayer insulating end portion. The first inorganic insulating layer may cover a portion of an upper surface of the buffer layer and expose another portion of the upper surface of the buffer layer in a portion of the non-display area. The upper organic layer and the buffer layer may contact each other at a portion of the upper surface of the buffer layer exposed by the first inorganic insulating layer.

According to an embodiment, the barrier end portion and the buffer end portion may be directly adjacent to the organic contact area.

According to an embodiment, the barrier end portion and the buffer end portion may overlap each other in a plan view.

According to an embodiment, the gate insulating end portion and the interlayer insulating end portion may be covered by the first inorganic insulating layer.

According to an embodiment, the gate insulating end portion and the interlayer insulating end portion may overlap each other in a plan view.

According to an embodiment, the display device may further include a dam disposed in a dam area formed in the non-display area; an organic encapsulation layer including at least a portion disposed on the first inorganic insulating layer in an area surrounded by the dam; a second inorganic insulating layer covering the organic encapsulation layer and disposed on the first inorganic insulating layer; a first upper insulating layer disposed on the second inorganic insulating layer; a first conductive pattern layer disposed on the first upper insulating layer; a second upper insulating layer covering the first conductive pattern layer and disposed on the first upper insulating layer; and a second conductive pattern layer disposed on the second upper insulating layer. The second inorganic insulating layer may include a second inorganic insulating end portion in the non-display area. The first upper insulating layer may include a first upper insulating end portion in the non- display area. The second upper insulating layer may include a second upper insulating end portion in the non-display area.

According to an embodiment, the organic contact area may be formed outside the dam area. The first conductive pattern layer and the second conductive pattern layer may form sensing electrodes that obtain information about a user's touch input.

According to an embodiment, the second inorganic insulating end portion, the first upper insulating end portion, and the second upper insulating end portion may overlap each other in a plan view.

According to an embodiment, the upper organic layer may cover the second conductive pattern layer, the barrier end portion, the buffer end portion, the first inorganic insulating end portion, the second inorganic insulating end portion, the first upper insulating end portion, and the second upper insulating end portion, and may be spaced apart from the gate insulating end portion and the interlayer insulating end portion.

According to an embodiment, the display device may further include a polarizing layer disposed on the upper organic layer. The polarizing layer, the upper organic layer, the first base, the first barrier layer, and the second base may have end portions that overlap each other.

According to an embodiment, the display device may further include an organic protective layer disposed on the second conductive pattern layer and spaced apart from the organic contact area; and a polarizing layer disposed on the upper organic layer. The upper organic layer may cover the organic protective layer.

According to embodiments of the disclosure, a method of manufacturing a display device including a non-display area and a display area may include providing a base layer including a first base, a first barrier layer on the first base, a second base on the first barrier layer, and a second barrier layer on the second base; disposing a buffer layer on the second barrier layer; disposing a gate insulating layer on the buffer layer; disposing an interlayer insulating layer on the gate insulating layer; exposing the buffer layer in a first exposed area which is a portion of the non-display area by removing at least portions of the gate insulating layer and the interlayer insulating layer; exposing the second base in a second exposed area which is a portion of the non-display area by removing at least portions of the second barrier layer and the buffer layer; forming a light emitting element on the base layer in the display area; forming a first inorganic insulating layer, at least a portion of which covers the light emitting element; forming an organic encapsulation layer on the first inorganic insulating layer; forming a second inorganic insulating layer on the organic encapsulation layer; forming a first upper insulating layer on the second inorganic insulating layer; forming a second upper insulating layer on the first upper insulating layer; exposing the first inorganic insulating layer by removing at least portions of the second inorganic insulating layer, the first upper insulating layer, and the second upper insulating layer; exposing the second base by removing at least a portion of the first inorganic insulating layer; and forming an upper organic layer over the display area and the non-display area. The forming of the upper organic layer may include contacting the upper organic layer and the second base in an organic contact area.

According to an embodiment, the method of manufacturing the display device may further include performing a cutting process based on a cutting line defined in the organic contact area.

According to an embodiment, the method of manufacturing the display device may further include patterning an active layer on the buffer layer. The exposing of the buffer layer may include forming a contact portion exposing the active layer.

According to an embodiment, the exposing of the buffer layer may include forming a first step area defined by end portions of the gate insulating layer and the interlayer insulating layer. The exposing of the second base in the second exposed area which is a portion of the non-display area by removing at least portions of the second barrier layer and the buffer layer may include forming a second step area defined by end portions of the second barrier layer and the buffer layer. The exposing of the second base by removing at least a portion of the first inorganic insulating layer may include forming an end portion of the first inorganic insulating layer between the first step area and the second step area.

According to an embodiment, the exposing of the second base in the second exposed area which is a portion of the non-display area by removing at least portions of the second barrier layer and the buffer layer may include etching the second barrier layer and the buffer layer using a first etch mask. The exposing of the first inorganic insulating layer may include etching the second inorganic insulating layer, the first upper insulating layer, and the second upper insulating layer using a second etch mask.

According to an embodiment, the method of manufacturing the display device may further include disposing a polarizing layer on the upper organic layer.

### BRIEF DESCRIPTION OF THE DRAWINGS

The above and other aspects, features, and advantages of the disclosure will become more apparent from the detailed description of embodiments with reference to the accompanying drawings, in which:

FIG. 1 is a schematic perspective view illustrating a display device according to an embodiment.

FIG. 2 is a schematic plan view illustrating the display device according to an embodiment.

FIG. 3 is a schematic cross-sectional view illustrating the display device according to an embodiment.

FIGS. 4 to 6 are schematic cross-sectional views taken along line A-A′ of FIG. 2.

FIG. 7 is a schematic plan view illustrating a mother substrate that includes unit cells to explain a method of manufacturing a display device according to an embodiment.

FIGS. 8 to 19 are schematic cross-sectional views illustrating each process step of the method of manufacturing the display device according to an embodiment.

FIGS. 20 to 22 are schematic cross-sectional views illustrating each process step of a method of manufacturing of the display device according to an embodiment.

FIGS. 23 to 26 are schematic cross-sectional views illustrating each process step of a method of manufacturing of the display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art. Various embodiments do not have to be exclusive nor limit the disclosure. For example, specific shapes, configurations, and characteristics of an embodiment may be used or implemented in another embodiment.

In the drawings, the sizes, thicknesses, ratios, and dimensions of the elements may be exaggerated for ease of description and for clarity. Like numbers refer to like elements throughout.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or.”

The term “at least one of”' is intended to include the meaning of “at least one selected from” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms “first,” “second,” etc. may be used herein to describe various elements, these elements should not be limited by these terms. These terms are only used to distinguish one element from another element. For instance, a first element could be termed a second element without departing from the teachings of the disclosure. Similarly, a second element could also be termed a first element, without departing from the scope of the disclosure.

As used herein, the expressions used in the singular such as “a,” “an,” and “the,” are intended to include the plural forms as well, unless the context clearly indicates otherwise.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, 10%, or 5% of the stated value.

It should be understood that the terms “comprise”, “include”, “have”, and the like are intended to specify the presence of stated features, integers, steps, operations, elements, components, and/or combinations of them but do not preclude the presence or addition of one or more other features, integers, steps, operations, elements, components, and/or combinations thereof.

In the disclosure, it will be understood that when an element (or region, layer, part, etc.) is referred to as being “on,” “connected to,” or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

The terms “overlap,” “overlapping,” or “overlapped” mean that a first object may be above or below or to a side of a second object, and vice versa. The term “overlap” may include layer, stack, face or facing, extending over, covering, or partly covering or any other suitable term as would be appreciated and understood by those of ordinary skill in the art.

When an element is described as “not overlapping” or “to not overlap” another element, this may include that the elements are spaced apart from each other, offset from each other, or set aside from each other or any other suitable term as would be appreciated and understood by those of ordinary skill in the art.

In the disclosure, when an element is “directly on,” “directly connected to,” or “directly coupled to” another element, there are no intervening elements present. For example, “directly on” may mean that two layers or two elements are disposed without an additional element such as an adhesion element therebetween.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The phrase “in a plan view” means viewing the object from the top, and the phrase “in a schematic cross-sectional view” means viewing a cross-section of which the object is vertically cut from the side. Hence, the expression “in a plan view” used herein may mean that an object is viewed in the third z direction from the top. The phrase “in a schematic cross-sectional view” means viewing a cross-section in the first x direction or the second y direction of which the object is vertically cut from the side. The third z direction also can be referred to as a “thickness direction.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The disclosure relates to a display device and a method of manufacturing the display device. Hereinafter, a display device and a method of manufacturing the display device according to embodiments will be described with reference to the attached drawings.

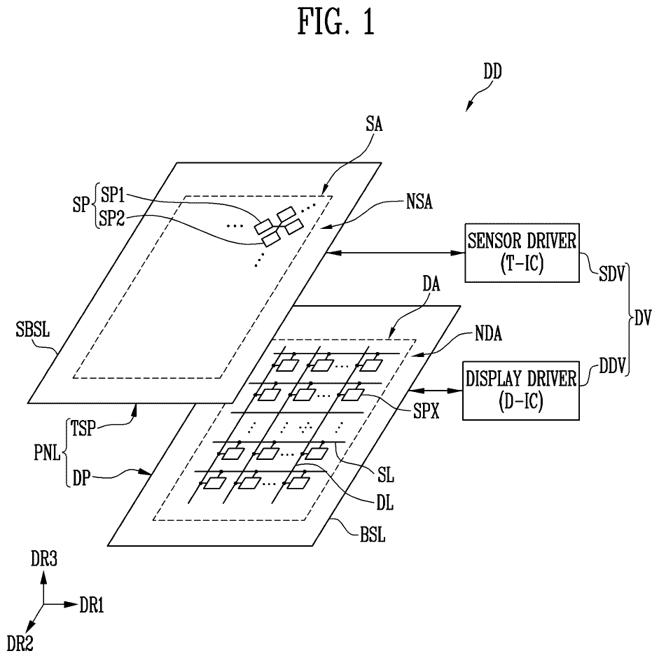

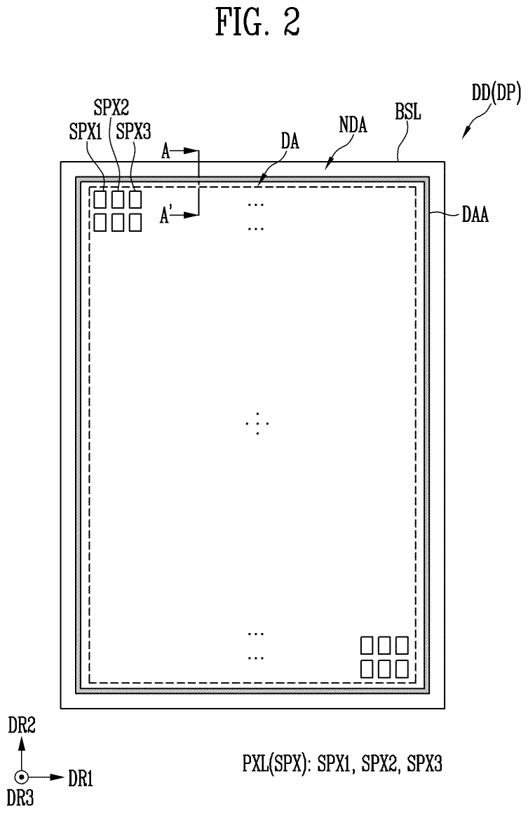

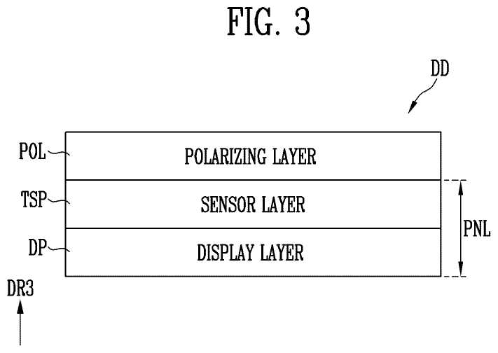

FIG. 1 is a perspective view schematically illustrating a display device according to an embodiment. FIG. 2 is a plan view schematically illustrating the display device according to an embodiment. FIG. 3 is a cross-sectional view schematically illustrating the display device according to an embodiment.

Referring to FIGS. 1 to 3, a display device DD may provide (or emit) light. The display device DD may include a panel PNL and a driving circuit unit DV for driving the panel PNL. The display device DD may further include a polarizing layer POL disposed on the panel PNL.

The panel PNL may include a display layer DP for displaying an image and a sensor layer TSP that senses a user's input (for example, a touch input). The display layer DP may be referred to as a display panel. The sensor layer TSP may be referred to as a sensing panel.

The panel PNL may include sub-pixels SPX and sensing electrodes SP. In an embodiment, the sub-pixels SPX may display an image in units of display frame periods. The sensing electrodes SP may sense a user's input (for example, a touch input) in units of sensing frame periods.

The display layer DP may output visual information (for example, an image). In an embodiment, the display layer DP may include an organic light emitting diode or a light emitting diode including an inorganic material. However, the disclosure is not limited to specific examples. Hereinafter, for convenience of description, an embodiment in which the display layer DP includes an organic light emitting diode will be described as an example.

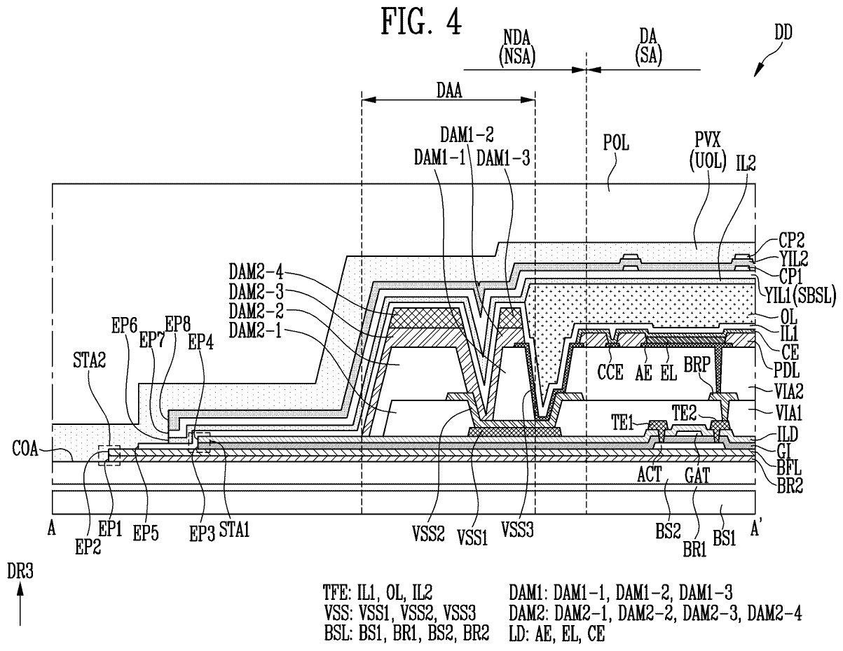

The display layer DP may include a base layer BSL and sub-pixels SPX provided on the base layer BSL, which include light emitting elements LD (see FIG. 4). The sub-pixels SPX may be arranged in a display area DA. The sub-pixels SPX may form a pixel PXL.

The base layer BSL (or display device DD) may include a display area DA where an image is displayed and a non-display area NDA that is an area other than the display area DA. The non-display area NDA may surround at least a portion of the display area DA.

The base layer BSL may form the basis of layers for forming the display layer DP. In an embodiment, the base layer BSL may include a multi-layer structure. In an embodiment, the base layer BSL may include a structure in which organic layers and inorganic layers are alternately stacked. For example, the base layer BSL may include a first base BS1 (see FIG. 4), a first barrier layer BR1 (see FIG. 4) on the first base BS1, a second base BS2 (see FIG. 4) on the first barrier layer BR1, and a second barrier layer BR2 (see FIG. 4) on the second base BS2.

The first base BS1 and the second base BS2 may include an organic material. The first barrier layer BR1 and the second barrier layer BR2 may include an inorganic material.

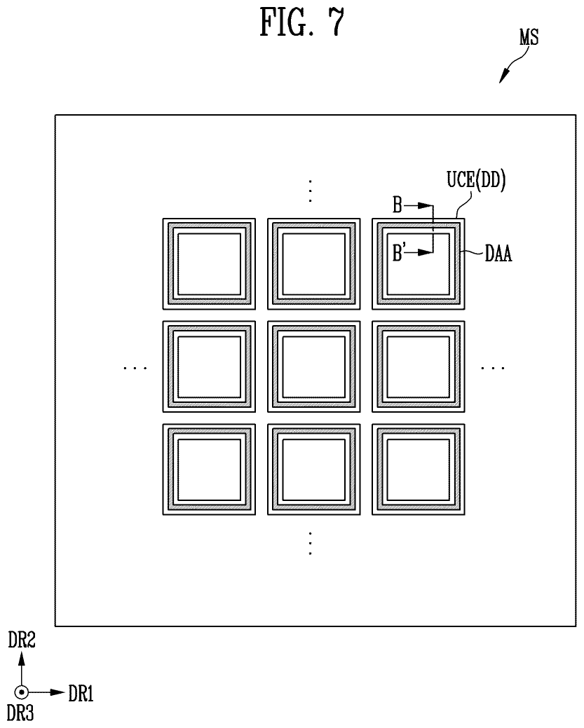

The base layer BSL may form the base of a mother substrate MS (see FIG. 7). At least a portion of the mother substrate MS may be cut to form each base layer BSL of the display device DD.

The pixel PXL (or sub-pixels SPX) may be arranged in an array structure such as a stripe, PENTILE™, or the like. However, the disclosure is not limited thereto, and various embodiments may be applied to the disclosure.

In an embodiment, the pixel PXL (or sub-pixels SPX) may include a first sub-pixel SPX1, a second sub-pixel SPX2, and a third sub-pixel SPX3. The first sub-pixel SPX1, the second sub-pixel SPX2, and the third sub-pixel SPX3 may be sub-pixels. At least one first sub-pixel SPX1, second sub-pixel SPX2, and third sub-pixel SPX3 may form a pixel PXL that emits light of various colors.

Each of the first sub-pixel SPX1, the second sub-pixel SPX2, and the third sub-pixel SPX3 may emit light of one color. For example, the first sub-pixel SPX1 may be a red pixel that emits red light (for example, a first color), the second sub-pixel SPX2 may be a green pixel that emits green light (for example, a second color), and the third sub-pixel SPX3 may be a blue pixel that emits blue light (for example, a third color). The red pixel may provide light in a wavelength range of about 600 nm to about 750 nm. The green pixel may provide light in a wavelength range of about 480 nm to about 560 nm. The blue pixel may provide light in a wavelength range of about 370 nm to about 460 nm.

In an embodiment, the number of second sub-pixels SPX2 may be greater than the number of first sub-pixels SPX1 and the number of third sub-pixels SPX3. However, the color, type, and/or number of the first, second, and third sub-pixels SPX1, SPX2, and SPX3 that form each pixel PXL are not limited to specific examples.

Scan lines SL, data lines DL, and sub-pixels SPX that are electrically connected to the scan lines SL and the data lines DL may be disposed in the display area DA. The sub-pixels SPX may be selected by a scan signal of a turn-on level supplied from the scan lines SL to receive a data signal from the data lines DL, and may emit light with a luminance corresponding to the data signal. Accordingly, an image corresponding to the data signal may be displayed in the display area DA.

Various wirings and/or built-in circuit parts connected to the sub-pixels SPX in the display area DA may be disposed in the non-display area NDA. For example, wirings may be disposed in the non-display area NDA to supply various power sources and control signals to the display area DA.

The sensor layer TSP may obtain information about a user's touch input. The sensing electrodes SP may include a first sensing electrode SP1 providing a first sensing signal and a second sensing electrode SP2 providing a second sensing signal. In an embodiment, such as a mutual capacitance method, the first sensing electrode SP1 may be a Tx (Transmitter) pattern electrode, and the second sensing electrode SP2 may be an Rx (Receiver) pattern electrode. Information about touch input (or touch event) may mean information including the location of the touch that a user wishes to provide. However, the disclosure is not limited thereto. In an embodiment, such as a self-capacitance method, the sensing electrodes SP may include a sensing electrode without distinguishing between the first sensing electrode SP1 and the second sensing electrode SP2.

The sensor layer TSP may be disposed (for example, directly disposed) on the display layer DP. The sensor layer TSP may include a sensor base layer SBSL and sensing electrodes SP formed on the sensor base layer SBSL. The sensing electrodes SP may be disposed in a sensing area SA on the sensor base layer SBSL.

The driving circuit unit DV may include a display driver DDV (D-IC) for driving the display layer DP and a sensor driver SDV (T-IC) for driving the sensor layer TSP.

The sensor base layer SBSL (or display device DD) may include a sensing area SA configured to detect a touch input or the like, and a non-sensing area NSA surrounding the sensing area SA. In an embodiment, the sensing area SA may be disposed to overlap at least one area of the display area DA. For example, the sensing area SA may correspond to the display area DA (for example, the sensing area SA overlaps the display area DA), and the non-sensing area NSA may correspond to the non-display area NDA (for example, the non-sensing area NSA overlaps the non-display area NDA). In case that a touch input or the like is provided on the display area DA, the touch input may be detected through the sensor layer TSP.

The sensor base layer SBSL may include one or more insulating layers (for example, a first upper insulating layer YIL1 (see FIG. 4)). For example, the first upper insulating layer YIL1 for forming the sensor base layer SBSL may be disposed on the display layer DP to form a base on which the sensing electrodes SP are formed.

The sensing area SA may be an area that may respond to a touch input, such as an active area of a sensor. The sensor layer TSP may obtain information about user input. Sensing lines that electrically connect the sensing electrodes SP to the sensor driver SDV and the like may be disposed in the non-sensing area NSA of the sensor layer TSP.

In an embodiment, first sensing electrodes SP1 may extend in a first direction DR1. The first sensing electrodes SP1 may be arranged in a second direction DR2. In an embodiment, second sensing electrodes SP2 may extend in the second direction DR2. The second sensing electrodes SP2 may be arranged in the first direction DR1. The second direction DR2 may differ from the first direction DR1; for example, the second direction DR2 may be perpendicular to the first direction DR1.

The driving circuit unit DV may include the display driver DDV for driving the display layer DP and the sensor driver SDV for driving the sensor layer TSP.

The display driver DDV may be electrically connected to the display layer DP to drive the sub-pixels SPX. The sensor driver SDV may be electrically connected to the sensor layer TSP to drive the sensor layer TSP.

In an embodiment, the display device DD may further include a dam area DAA. For example, the dam area DAA may be defined (for example, disposed) in the non-display area NDA (or the non-sensing area NSA). The dam area DAA may be an area where a first dam DAM1 (see FIG. 4) and/or a second dam DAM2 are disposed.

The dam area DAA may be disposed at the periphery of the display area DA (or sensing area SA). The dam area DAA may entirely surround the display area DA (or sensing area SA) in a plan view. For example, the dam area DAA may have a closed-loop structure surrounding the display area DA (or sensing area SA).

The plane defined in this specification may extend in both the first direction DR1 and the second direction DR2 and may be defined based on a plane on which the base layer BSL is disposed, as seen in a plan view. In an embodiment, a third direction DR3 may represent a thickness direction of the base layer BSL, which is perpendicular to the plane in a plan view. The third direction DR3 may also correspond to a direction in which light is emitted from the display device DD.

The polarizing layer POL may be disposed on the panel PNL (for example, the sensor layer TSP). Light provided from the display layer DP may pass through the polarizing layer POL and be output to the outside. The polarizing layer POL may include materials having various polarization properties. For example, the polarizing layer POL may include a phase retardation layer and may also include a wire grid polarization layer.

The display device DD according to embodiments will be described with reference to FIGS. 4 to 6, which show schematic cross-sectional structures of the display device DD. FIGS. 4 to 6 are schematic cross-sectional views taken along line A-A′ of FIG. 2. These figures illustrate areas from the non-display area NDA, including the dam area DAA, to the display area DA.

A display device DD according to a first embodiment will be described with reference to FIG. 4.

As described above, the display area DA and the sensing area SA may overlap each other in a plan view, and the non-display area NDA and the non-sensing area NSA may overlap each other in a plan view. Hereinafter, for convenience of description, a cross-sectional view of the display device DD will be described based on the display area DA and the non-display area NDA. Technical descriptions related to the display area DA may be equally applied to the structure related to the sensing area SA, and technical descriptions related to the non-display area NDA can be similarly applied to the structure related to the non-sensing area NSA.

In an embodiment, the display device DD may include the base layer BSL.

The base layer BSL may include the first base BS1 and the second base BS2, both including an organic material, and the first barrier layer BR1 and the second barrier layer BR2, both including an inorganic material. For example, the organic material may include, but is not limited to, at least one of an acrylic resin, an epoxy resin, a phenol resin, a polyamide resin, a polyimide resin, a polyester resin, a polyphenylenesulfide resin, and benzocyclobutene (BCB). In an embodiment, the first base BS1 and the second base BS2 may include a polyimide resin. The inorganic material may include, but is not limited to, at least one of silicon nitride (SiNₓ), silicon oxide (SiOₓ), silicon oxynitride (SiOₓN_{y}), and aluminum oxide (AlₓO_{y}).

The second barrier layer BR2 may be disposed over the display area DA and the non-display area NDA on the second base BS2, while exposing at least a portion of the second base BS2. A portion of an upper surface of the second base BS2, exposed by the second barrier layer BR2, may be disposed in the non-display area NDA and defined outside the dam area DAA. In an embodiment, the second base BS2 may not be exposed by the second barrier layer BR2 in the display area DA.

At least a portion of the second base BS2 exposed by the second barrier layer BR2 may include an organic contact area COA. The organic contact area COA may be a part of the base layer BSL and may be an area where the second base BS2, which includes an organic material, contacts an upper organic layer UOL. The organic contact area COA may be included in the non-display area NDA.

An end portion of the second barrier layer BR2 (for example, a barrier end portion EP1) may be directly adjacent to the organic contact area COA. The barrier end portion EP1 of the second barrier layer BR2 may be directly adjacent to the upper organic layer UOL.

In an embodiment, the display device DD may include a buffer layer BFL.

The buffer layer BFL may be disposed over the display area DA and the non-display area NDA and may be disposed on the second barrier layer BR2. The buffer layer BFL may be disposed between an active layer ACT and the base layer BSL. The buffer layer BFL may expose at least a portion of the second base BS2. In an embodiment, the buffer layer BFL may contact the active layer ACT in the display area DA. The buffer layer BFL may include an inorganic material. For example, the buffer layer BFL may include, but is not limited to, at least one of silicon nitride (SiNₓ), silicon oxide (SiOₓ), silicon oxynitride (SiOₓN_{y}), and aluminum oxide (AlₓO_{y}).

An end portion of the buffer layer BFL (for example, a buffer end portion EP2) may be directly adjacent to the organic contact area COA. The buffer end portion EP2 of the buffer layer BFL may be directly adjacent to the upper organic layer UOL.

In an embodiment, the second barrier layer BR2 and the buffer layer BFL may extend further toward an edge of the display device DD than a gate insulating layer GI and an interlayer insulating layer ILD. The barrier end portion EP1 and the buffer end portion EP2 may correspond to (for example, overlap) each other in a plan view. For example, the second barrier layer BR2 and the buffer layer BFL may have edges corresponding to each other. For example, the second barrier layer BR2 and the buffer layer BFL may be etched using a common mask.

The second barrier layer BR2 and the buffer layer BFL may form a second step area STA2. For example, the second barrier layer BR2 and the buffer layer BFL may extend to a lesser extent than the second base BS2, thereby forming the second step area STA2.

A portion of the buffer layer BFL may be exposed by a first inorganic insulating layer IL1, and a portion of an upper surface of the buffer layer BFL exposed by the first inorganic insulating layer ILI may contact the upper organic layer UOL.

In an embodiment, the display device DD may include the active layer ACT.

The active layer ACT may be disposed on the buffer layer BFL in the display area DA. The active layer ACT may include various semiconductor materials. For example, the active layer ACT may include, but is not limited to, at least one of polysilicon, low temperature polycrystalline silicon (LTPS), amorphous silicon, and oxide semiconductor.

In an embodiment, the display device DD may include the gate insulating layer GI.

The gate insulating layer GI may be disposed over both the display area DA and the non-display area NDA on the buffer layer BFL, and it may cover the active layer ACT. The gate insulating layer GI may expose at least a portion of the buffer layer BFL. The gate insulating layer GI may include an inorganic material. For example, the buffer layer BFL may include, but is not limited to, at least one of silicon nitride (SiNₓ), silicon oxide (SiOₓ), silicon oxynitride (SiOₓN_{y}), and aluminum oxide (AlₓO_{y}).

An end portion of the gate insulating layer GI (for example, a gate insulating end portion EP3) may be spaced apart from the organic contact area COA and the second step area STA2. The gate insulating end portion EP3 of the gate insulating layer GI may be covered by the first inorganic insulating layer IL1.

In an embodiment, the display device DD may include a gate conductive layer GAT.

The gate conductive layer GAT may be disposed on the gate insulating layer GI in the display area DA and may overlap the active layer ACT in a plan view. The gate conductive layer GAT may include various conductive materials. For example, the gate conductive layer GAT may include, but is not limited to, at least one of gold (Au), silver (Ag), aluminum (Al), molybdenum (Mo), chromium (Cr), titanium (Ti), nickel (Ni), neodymium (Nd), copper (Cu), and platinum (Pt).

In an embodiment, the display device DD may include the interlayer insulating layer ILD.

The interlayer insulating layer ILD may be disposed over both the display area DA and the non-display area NDA on the gate insulating layer GI, and it may cover the gate conductive layer GAT. The interlayer insulating layer ILD may expose at least a portion of the buffer layer BFL. The interlayer insulating layer ILD may include an inorganic material. For example, the interlayer insulating layer ILD may include, but is not limited to, at least one of silicon nitride (SiNₓ), silicon oxide (SiOₓ), silicon oxynitride (SiOₓN_{y}), and aluminum oxide (AlₓO_{y}).

An end portion of the interlayer insulating layer ILD (for example, an interlayer insulating end portion EP4) may be spaced apart from the organic contact area COA and the second step area STA2. The interlayer insulating end portion EP4 of the interlayer insulating layer ILD may be covered by the first inorganic insulating layer IL1. The gate insulating layer GI and the interlayer insulating layer ILD may be physically spaced apart from the organic contact area COA and the upper organic layer UOL. For example, the gate insulating end portion EP3 and the interlayer insulating end portion EP4 may be spaced apart from the upper organic layer UOL.

In an embodiment, the gate insulating end portion EP3 and the interlayer insulating end portion EP4 may correspond to (for example, overlap) each other in a plan view. For example, the gate insulating layer GI and the interlayer insulating layer ILD may have edges corresponding to each other. For example, the gate insulating layer GI and the interlayer insulating layer ILD may be etched using a common mask.

The gate insulating layer GI and the interlayer insulating layer ILD may form a first step area STA1. For example, the gate insulating layer GI and the interlayer insulating layer ILD may extend to a lesser extent than the second barrier layer BR2 and the buffer layer BFL, thereby forming the first step area STA1.

In an embodiment, the display device DD may include first and second transistor electrodes TE1 and TE2 and a first cathode power source supply line VSS1.

The first and second transistor electrodes TE1 and TE2 may be disposed on the interlayer insulating layer ILD in the display area DA, and electrically connected to the active layer ACT through a contact member penetrating the interlayer insulating layer ILD and the gate insulating layer GI. The first and second transistor electrodes TE1 and TE2 may serve as either a source electrode and a drain electrode, or a drain electrode and a source electrode.

The first cathode power source supply line VSS1 may be disposed on the interlayer insulating layer ILD in the non-display area NDA. In an embodiment, a portion of the first cathode power source supply line VSS1 may be disposed in the dam area DAA and may overlap the first dam DAM1 in a plan view.

The first and second transistor electrodes TE1 and TE2 and the first cathode power source supply line VSS1 may be patterned using the same process and may include the same conductive material. The first and second transistor electrodes TE1 and TE2 and the first cathode power source supply line VSS1 may include various conductive materials. For example, the first and second transistor electrodes TE1 and TE2 and the first cathode power source supply line VSS1 may include, but are not limited to, at least one of gold (Au), silver (Ag), aluminum (Al), molybdenum (Mo), chromium (Cr), titanium (Ti), nickel (Ni), neodymium (Nd), copper (Cu), and platinum (Pt).

The first and second transistor electrodes TE1 and TE2, the gate conductive layer GAT, and the active layer ACT may form a pixel circuit for driving the light emitting element LD. For example, the pixel circuit may include a driving transistor, a switching transistor, and the like, and may further include a capacitor.

In an embodiment, the display device DD may include a first via layer VIA1 and a (2-1)th dam DAM2-1.

The first via layer VIA1 may be disposed on the interlayer insulating layer ILD in the display area DA. The first via layer VIA1 may cover portions of the first and second transistor electrodes TE1 and TE2. The first via layer VIA1 may include an organic material.

The (2-1)th dam DAM2-1 may be disposed on the interlayer insulating layer ILD in the non-display area NDA (for example, the dam area DAA). The (2-1)th dam DAM2-1 may cover a portion of the first cathode power source supply line VSS1. The (2-1)th dam DAM2-1 may include an organic material. The (2-1)th dam DAM2-1 may form a lower part of the second dam DAM2.

The first via layer VIA1 and the (2-1)th dam DAM2-1 may be patterned using the same process and may include the same material.

In an embodiment, the display device DD may include a bridge layer BRP and a second cathode power source supply line VSS2.

The bridge layer BRP may be disposed on the first via layer VIA1 in the display area DA, and may be electrically connected to the second transistor electrode TE2 through a contact member penetrating the first via layer VIA1.

The second cathode power source supply line VSS2 may be disposed on the first via layer VIA1 in the display area DA and the (2-1)th dam DAM2-1 in the non-display area NDA. The second cathode power source supply line VSS2 may be electrically connected to the first cathode power source supply line VSS1 through a contact member penetrating the first via layer VIA1 and the (2-1)th dam DAM2-1. In an embodiment, a portion of the second cathode power source supply line VSS2 may be disposed in the dam area DAA and may overlap the first dam DAM1 in a plan view.

The bridge layer BRP and the second cathode power source supply line VSS2 may be patterned using the same process and may include the same conductive material. The bridge layer BRP and the second cathode power source supply line VSS2 may include various conductive materials. For example, the bridge layer BRP and the second cathode power source supply line VSS2 may include, but are not limited to, at least one of gold (Au), silver (Ag), aluminum (Al), molybdenum (Mo), chromium (Cr), titanium (Ti), nickel (Ni), neodymium (Nd), copper (Cu), and platinum (Pt).

In an embodiment, the display device DD includes a second via layer VIA2, a (1-1)th dam DAM1-1, and a (2-2)th dam DAM2-2.

The second via layer VIA2 may be disposed on the first via layer VIA1 in the display area DA. The second via layer VIA2 may cover a portion of the bridge layer BRP and may also cover a portion of the second cathode power source supply line VSS2. The second via layer VIA2 may include an organic material.

The (1-1)th dam DAM1-1 may be disposed on the second cathode power source supply line VSS2, which is disposed on the first cathode power source supply line VSS1, in the non-display area NDA (for example, the dam area DAA). The (1-1)th dam DAM1-1 may include an organic material. The (1-1)th dam DAM1-1 may form a lower part of the first dam DAM1.

The (2-2)th dam DAM2-2 may be disposed on the (2-1)th dam DAM2-1 in the non-display area NDA (for example, the dam area DAA). The (2-2)th dam DAM2-2 may cover a portion of the second cathode power source supply line VSS2. The (2-2)th dam DAM2-2 may include an organic material. The (2-2)th dam DAM2-2 may form a middle lower part of the second dam DAM2.

The second via layer VIA2, the (1-1)th dam DAM1-1, and the (2-2)th dam DAM2-2 may be patterned using the same process and may include the same material.

In an embodiment, the display device DD may include an anode electrode AE, a cathode connection electrode CCE, and a third cathode power source supply line VSS3.

The anode electrode AE may be disposed on the second via layer VIA2 in the display area DA. The anode electrode AE may be electrically connected to the bridge layer BRP through a contact member penetrating the second via layer VIA2. The anode electrode AE may include a multi-layer structure and may include various conductive materials. For example, the anode electrode AE may include at least one of a transparent conductive material and a reflective conductive material. The anode electrode AE may include, but is not limited to, a structure in which ITO/Ag/ITO are sequentially stacked.

The cathode connection electrode CCE may be disposed on the second via layer VIA2 in the display area DA. The cathode connection electrode CCE may be electrically connected to a cathode electrode CE.

The third cathode power source supply line VSS3 may be disposed on the second via layer VIA2 and the (1-1)th dam DAM1-1 in the non-display area NDA. The third cathode power source supply line VSS3 may be electrically connected to the second cathode power source supply line VSS2 through a contact member penetrating the second via layer VIA2 and the (1-1)th dam DAM1-1. In an embodiment, a portion of the third cathode power source supply line VSS3 may be disposed in the dam area DAA and may overlap the first dam DAM1 in a plan view.

The first to third cathode power source supply lines VSS1 to VSS3 may form a cathode power source supply line VSS. Accordingly, a cathode signal (for example, a cathode voltage) may be supplied to the cathode electrode CE to enable the light emitting element LD to emit light.

The anode electrode AE, the cathode connection electrode CCE, and the third cathode power source supply line VSS3 may be patterned using the same process and may include the same conductive material.

In an embodiment, the display device DD may include a pixel defining layer PDL, a (1-2)th dam DAM1-2, and a (2-3)th dam DAM2-3.

The pixel defining layer PDL may be disposed in the display area DA and may cover the anode electrode AE and the cathode connection electrode CCE. The pixel defining layer PDL may define an area where a light emitting layer EL and the anode electrode AE are electrically connected to each other.

The pixel defining layer PDL may include an inorganic material. For example, the pixel defining layer PDL may include, but is not limited to, at least one of silicon oxide (SiOₓ) and silicon nitride (SiNₓ). The pixel defining layer PDL may include a multi-layer structure. For example, the pixel defining layer PDL may include a multi-layer structure in which silicon oxide (SiOₓ) and silicon nitride (SiNₓ) are alternately stacked. In another embodiment, the pixel defining layer PDL may include an organic material.

The (1-2)th dam DAM1-2 may be disposed on the (1-1)th dam DAM1-1 in the non-display area NDA (for example, the dam area DAA). The (1-2)th dam DAM1-2 may cover a portion of the second cathode power source supply line VSS2. The (1-2)th dam DAM1-2 may form a middle part of the first dam DAM1.

The (2-3)th dam DAM2-3 may be disposed on the (2-2)th dam DAM2-2 in the non-display area NDA (for example, the dam area DAA). The (2-3)th dam DAM2-3 may cover a portion of the second cathode power source supply line VSS2. The (2-3)th dam DAM2-3 may form a middle upper part of the second dam DAM2.

The pixel defining layer PDL, the (1-2)th dam DAM1-2, and the (2-3)th dam DAM2-3 may be patterned using the same process and may include the same material.

In an embodiment, the display device DD may include the light emitting layer EL.

The light emitting layer EL may be disposed on the anode electrode AE in the display area DA and may be electrically connected between the anode electrode AE and the cathode electrode CE. In an embodiment, the light emitting layer EL may emit light of different colors depending on corresponding sub-pixels SPX. For example, the light emitting layer EL included in the first sub-pixel SPX1 may emit light of a first color, the light emitting layer EL included in the second sub-pixel SPX2 may emit light of a second color, and the light emitting layer EL included in the third sub-pixel SPX3 may emit light of a third color.

The light emitting layer EL may be manufactured based on various process methods such as a deposition process, a coating process, or the like. The light emitting layer EL may include a plurality of layers. For example, the light emitting layer EL may include a hole transport part, a light emitting part (or light generating part), and an electron transport part. Each part forming the light emitting layer EL may include an organic material, and in an embodiment, may further include a metal-containing compound, an inorganic material such as quantum dots, or the like.

The hole transport part may include a multi-layer structure having multiple layers of different materials. As an example, the hole transport part may include a hole injection layer and a hole transport layer, and in an embodiment, may further include a light emitting auxiliary layer, an electron blocking layer, and the like.

The light emitting part may include a material configured to emit light of one color. The light emitting part may include a host and a dopant. The host of the light emitting part may be a light emitting material configured to capture carriers (electrons and holes) that generate light, and may induce efficient generation of excitons. The dopant may include a phosphorescent dopant or a fluorescent dopant. In an embodiment, examples of the dopant are not particularly limited. In an embodiment, the dopant may include an organic material, a metal complex, or the like.

The electron transport part may include a multi-layer structure having multiple layers of different materials. The electron transport part may include an electron injection layer and an electron transport layer, and in an embodiment, may further include an electron buffer layer, a hole blocking layer, and the like.

In an embodiment, the display device DD may include the cathode electrode CE.

The cathode electrode CE may be disposed on the pixel defining layer PDL and the light emitting layer EL in the display area DA. The cathode electrode CE may include various conductive materials. For example, the cathode electrode CE may include silver (Ag) and may further include an additional metal. The additional metal may include, but is not limited to, at least one of magnesium (Mg), aluminum (Al), copper (Cu), calcium (Ca), and barium (Ba). For example, the cathode electrode CE may include a silver-magnesium (AgMg) alloy. However, the present disclosure is not limited thereto. In an embodiment, the cathode electrode CE may include various transparent conductive materials.

In an embodiment, the anode electrode AE, the light emitting layer EL, and the cathode electrode CE may form the light emitting element LD.

In an embodiment, the display device DD may include a (1-3)th dam DAM1-3 and a (2-4)th dam DAM2-4.

The (1-3)th dam DAM1-3 may be disposed on the (1-2)th dam DAM1-2 in the non-display area NDA (for example, the dam area DAA). The (1-3)th dam DAM1-3 may cover the second and third cathode power source supply lines VSS2 and VSS3. The (1-3)th dam DAM1-3 may form an upper part of the first dam DAM1.

The (2-4)th dam DAM2-4 may be disposed on the (2-3)th dam DAM2-3 in the non-display area NDA (for example, the dam area DAA). The (2-4)th dam DAM2-4 may cover the interlayer insulating layer ILD and the second cathode power source supply line VSS2. The (2-4)th dam DAM2-4 may form an upper part of the second dam DAM2.

The (1-3)th dam DAM1-3 and the (2-4)th dam DAM2-4 may be patterned using the same process and may include the same material. For example, the (1-3)th dam DAM1-3 and the (2-4)th dam DAM2-4 may include, but are not limited to, an organic material.

The (1-1)th dam DAM1-1, the (1-2)th dam DAM1-2, and the (1-3)th dam DAM1-3 may form the first dam DAM1. The first dam DAM1 may be an inner dam closer to the display area DA than the second dam DAM2. The (2-1)th dam DAM2-1, the (2-2)th dam DAM2-2, the (2-3)th dam DAM2-3, and the (2-4)th dam DAM2-4 may form the second dam DAM2. The second dam DAM2 may be positioned farther from the display area DA than the first dam DAM1, serving as an outer dam.

In an embodiment, the display device DD may include an encapsulation layer TFE. The encapsulation layer TFE may include a first inorganic insulating layer IL1, an organic encapsulation layer OL, and a second inorganic insulating layer IL2.

The first inorganic insulating layer IL1 may be disposed over the display area DA and the non-display area NDA, and may cover (for example, passivate) the cathode electrode CE, the third cathode power source supply line VSS3, the first dam DAM1, the second dam DAM2, the interlayer insulating layer ILD, the interlayer insulating end portion EP4, the gate insulating end portion EP3, and the buffer layer BFL. The first inorganic insulating layer IL1 may include an inorganic material. For example, the first inorganic insulating layer IL1 may include, but is not limited to, at least one of silicon nitride (SiNₓ), silicon oxide (SiOₓ), silicon oxynitride (SiOₓN_{y}), and aluminum oxide (AlₓO_{y}).

The first inorganic insulating layer IL1 may expose at least a portion of the upper surface of the buffer layer BFL. The first inorganic insulating layer IL1 may expose the barrier end portion EP1 and the buffer end portion EP2. The first inorganic insulating layer IL1 may not expose the interlayer insulating end portion EP4 and the gate insulating end portion EP3.

The first inorganic insulating layer IL1 may extend further than the gate insulating layer GI and the interlayer insulating layer ILD, but not as far as the buffer layer BFL and the second barrier layer BR2. Accordingly, an end portion of the first inorganic insulating layer IL1 (for example, a first inorganic insulating end portion EP5) may be disposed between the first step area STA1 and the second step area STA2.

The organic encapsulation layer OL may be disposed on the first inorganic insulating layer IL1 in the dam area DAA. The organic encapsulation layer OL may be disposed in an area surrounded by the first dam DAM1 and the second dam DAM2. Accordingly, in case that the organic encapsulation layer OL is provided in the display area DA, the risk of the organic encapsulation layer OL spreading may be reduced by the first dam DAM1 and the second dam DAM2.

The second inorganic insulating layer IL2 may be disposed over the display area DA and the non-display area NDA, and may cover (for example, passivate) the organic encapsulation layer OL and the first inorganic insulating layer IL1. The second inorganic insulating layer IL2 may include an inorganic material. For example, the second inorganic insulating layer IL2 may include, but is not limited to, at least one of silicon nitride (SiNₓ), silicon oxide (SiOₓ), silicon oxynitride (SiOₓN_{y}), and aluminum oxide (AlₓO_{y}).

The second inorganic insulating layer IL2 may expose at least a portion of an upper surface of the first inorganic insulating layer IL1. The second inorganic insulating layer IL2 may expose the first inorganic insulating end portion EP5 of the first inorganic insulating layer IL1.

The second inorganic insulating layer IL2 may include a second inorganic insulating end portion EP6. The second inorganic insulating layer IL2 may extend further than the gate insulating layer GI and the interlayer insulating layer ILD, but not as far as the first inorganic insulating layer IL1, the buffer layer BFL, and the second barrier layer BR2.

In an embodiment, the display device DD may include the first upper insulating layer YIL1, a first conductive pattern layer CP1, a second upper insulating layer YIL2, a second conductive pattern layer CP2, and an organic protective layer PVX.

The first upper insulating layer YIL1, the first conductive pattern layer CP1, the second upper insulating layer YIL2, the second conductive pattern layer CP2, and the organic protective layer PVX may form the sensor layer TSP. For example, the first and second conductive pattern layers CP1 and CP2 may form the sensing electrodes SP. In an embodiment, at least portions of the first and second conductive pattern layers CP1 and CP2 may form the first sensing electrode SP1, and at least portions of the first and second conductive pattern layers CP1 and CP2 may form the second sensing electrode SP2.

The first upper insulating layer YIL1 may be disposed over the display area DA and the non-display area NDA on the second inorganic insulating layer IL2. The first upper insulating layer YIL1 may include an inorganic material. For example, the first upper insulating layer YIL1 may include, but is not limited to, at least one of silicon nitride (SiNₓ), silicon oxide (SiOₓ), silicon oxynitride (SiOₓN_{y}), and aluminum oxide (AlₓO_{y}).

The first upper insulating layer YIL1 may form the sensor base layer SBSL. The first upper insulating layer YIL1 may form a base on which other layers forming the sensor layer TSP are disposed.

The first upper insulating layer YIL1 may expose at least a portion of the upper surface of the first inorganic insulating layer IL1. The first upper insulating layer YIL1 may expose the first inorganic insulating end portion EP5 of the first inorganic insulating layer IL1.

The first upper insulating layer YIL1 may include a first upper insulating end portion EP7.

The second upper insulating layer YIL2 may be disposed over the display area DA and the non-display area NDA on the first upper insulating layer YIL1, and may cover the first conductive pattern layer CP1. The second upper insulating layer YIL2 may include an inorganic material. For example, the second upper insulating layer YIL2 may include, but is not limited to, at least one of silicon nitride (SiNₓ), silicon oxide (SiOₓ), silicon oxynitride (SiOₓN_{y}), and aluminum oxide (AlₓO_{y}). In another embodiment, the second upper insulating layer YIL2 may include an organic material.

The second upper insulating layer YIL2 may separate the first conductive pattern layer CP1 and the second conductive pattern layer CP2.

The second upper insulating layer YIL2 may expose at least a portion of the upper surface of the first inorganic insulating layer IL1. The second upper insulating layer YIL2 may expose the first inorganic insulating end portion EP5 of the first inorganic insulating layer IL1.

The second upper insulating layer YIL2 may include a second upper insulating end portion EP8.

In an embodiment, the second inorganic insulating end portion EP6, the first upper insulating end portion EP7, and the second upper insulating end portion EP8 may have edges corresponding to (for example, overlap) each other. For example, the second inorganic insulating layer IL2, the first upper insulating layer YIL1, and the second upper insulating layer YIL2 may be etched using a common mask.

The first conductive pattern layer CP1 may be disposed on the first upper insulating layer YIL1. The second conductive pattern layer CP2 may be disposed on the second upper insulating layer YIL2. The first conductive pattern layer CP1 and the second conductive pattern layer CP2 may be disposed on different layers. The first conductive pattern layer CP1 and the second conductive pattern layer CP2 may partially overlap each other in a plan view. In an embodiment, the first conductive pattern layer CPI and the second conductive pattern layer CP2 may overlap the pixel defining layer PDL in a plan view.

The first conductive pattern layer CP1 and the second conductive pattern layer CP2 may include a single or multiple metal layers. The first conductive pattern layer CP1 and the second conductive pattern layer CP2 may include, but are not limited to, at least one of various metal materials such as gold (Au), silver (Ag), aluminum (Al), molybdenum (Mo), chromium (Cr), titanium (Ti), nickel (Ni), neodymium (Nd), copper (Cu), and platinum (Pt), or an alloy thereof. In an embodiment, the first conductive pattern layer CPI and the second conductive pattern layer CP2 may include, but are not limited to, at least one of various transparent conductive materials, such as silver nanowires (AgNW), indium tin oxide (ITO), indium zinc oxide (IZO), indium gallium zinc oxide (IGZO), aluminum zinc oxide (AZO), indium tin zinc oxide (ITZO), zinc oxide (ZnO), tin oxide (SnO₂), carbon nano tubes, or graphene.

The organic protective layer PVX may be disposed over the display area DA and the non-display area NDA. The organic protective layer PVX may cover the second conductive pattern layer CP2, the second upper insulating layer YIL2, the first inorganic insulating layer IL1, the buffer layer BFL, and the second base BS2. The organic protective layer PVX may include an organic material. For example, the organic protective layer PVX may include, but is not limited to, at least one of an acrylic resin, an epoxy resin, a phenol resin, a polyamide resin, a polyimide resin, a polyester resin, a polyphenylenesulfide resin, and benzocyclobutene (BCB).

The organic protective layer PVX may cover the barrier end portion EP1, the buffer end portion EP2, the first inorganic insulating end portion EP5, the second inorganic insulating end portion EP6, the first upper insulating end portion EP7, and the second upper insulating end portion EP8. The organic protective layer PVX may be spaced apart from the gate insulating end portion EP3 and the interlayer insulating end portion EP4.

The organic protective layer PVX may be directly adjacent to the second step area STA2. The organic protective layer PVX may be spaced apart from the first step area STA1.

In an embodiment, the display device DD may include the polarizing layer POL.

The polarizing layer POL may be disposed over the display area DA and the non-display area NDA and may cover the organic protective layer PVX. As described above, the polarizing layer POL may include various materials with polarizing properties.

The polarizing layer POL, the organic protective layer PVX, the first base BS1, the first barrier layer BR1, and the second base BS2 may include end portions that overlap each other. For example, as the mother substrate MS (see FIG. 7) is cut, display devices DD may be separated from each other, and the end portions of the polarizing layer POL, the organic protective layer PVX, the first base BS1, the first barrier layer BR1, and the second base BS2 may be defined.

In an embodiment, the organic protective layer PVX may be the upper organic layer UOL forming the organic contact area COA.

For example, the organic protective layer PVX may contact the second base BS2 in the organic contact area COA. For example, the organic protective layer PVX may be formed after the second base BS2 is exposed, and a portion of the organic protective layer PVX may be directly adjacent to the second base BS2 through a portion of the exposed second base BS2.

As described above, since the organic protective layer PVX and the second base BS2 may include an organic material, organic layers may be continuously disposed through the organic contact area COA.

The organic contact area COA may be formed adjacent to an edge of the display device DD. The organic contact area COA may be further spaced apart from the display area DA than other layers disposed between the organic protective layer PVX and the second base BS2. The organic contact area COA may be directly adjacent to the edge of the display device DD.

In an embodiment, as the organic contact area COA is formed, the risk of impurities such as moisture or oxygen penetrating into the display device DD may be reduced. For example, a structure that blocks impurities such as moisture may be formed by continuously disposing organic layers on the outside of the display device DD. Accordingly, issues affecting the reliability of the display device DD due to impurities or similar factors may be reconsidered.

In an embodiment, as the organic contact area COA is formed, the risk of delamination of inorganic layers formed on the base layer BSL may be reduced. For example, as the organic contact area COA is formed outside the various inorganic layers on the base layer BSL, the upper organic layer UOL may cover the end portions of the inorganic layers and the upper surface of the inorganic layers. Even if stress is generated in the display device DD during a manufacturing process of the display device DD, the upper organic layer UOL may reduce the risk of delamination of the inorganic layers.

For example, layers for manufacturing the display device DD may be formed on the mother substrate MS, and the polarizing layer POL may be formed. Thereafter, the display device DD may be manufactured by performing a cutting process on the mother substrate MS. Experimentally, in case that the polarizing layer POL is cut, a portion of the polarizing layer POL shrinks, causing stress from the non-display area NDA to the display area DA. The stress caused may be applied throughout the components of the display device DD and may induce delamination of the inorganic layers on the base layer BSL. However, according to the embodiment, as the organic contact area COA is formed, the upper organic layer UOL may adequately cover the inorganic layers and the risk of delamination described above may be reduced.

In an embodiment, the formation of the organic contact area COA may reduce the risk of delamination of the inorganic layers, allowing the cutting area on the mother substrate MS to be expanded. This expansion improves process convenience and reduces the risk of process deviation by securing a larger process margin for the cutting process.

In an embodiment, an etching process may be performed on the insulating layers to define the organic contact area COA. This etching process may be combined with the etching process for other layers on the base layer BSL, thereby reducing mask consumption.

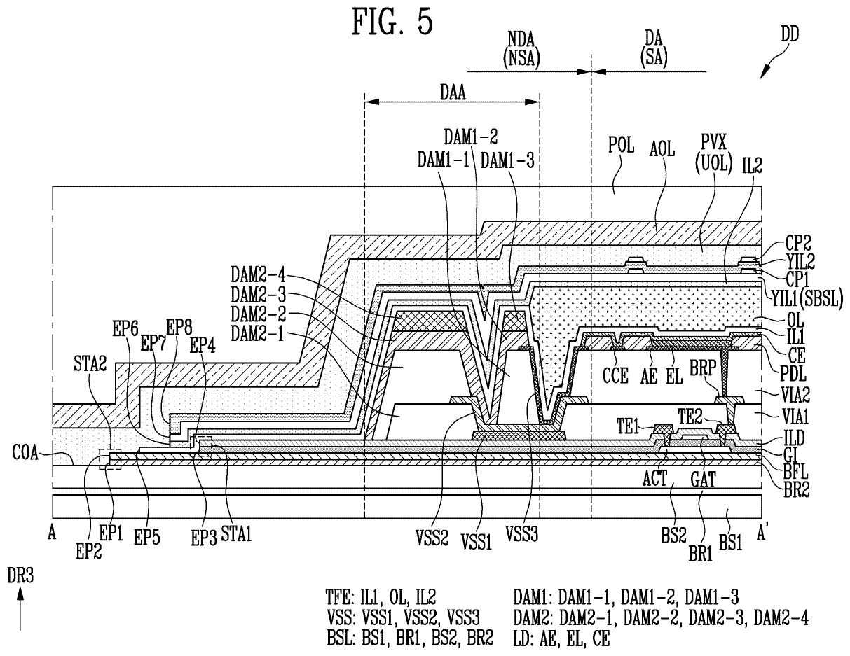

A display device DD according to a second embodiment will be described with reference to FIG. 5. Content overlapping with the above-described content will be briefly described or omitted.

The display device DD according to the second embodiment shown in FIG. 5 may be different from the display device DD according to the embodiment described with reference to FIG. 4 in that it further includes an additional organic protective layer AOL.

In an embodiment, the display device DD may further include the additional organic protective layer AOL disposed on the organic protective layer PVX that functions as the upper organic layer UOL.

The additional organic protective layer AOL may be disposed over the display area DA and the non-display area NDA on the organic protective layer PVX. The additional organic protective layer AOL may include an organic material. For example, the additional organic protective layers AOL may include, but is not limited to, at least one of an acrylic resin, an epoxy resin, a phenol resin, a polyamide resin, a polyimide resin, a polyester resin, a polyphenylenesulfide resin, and benzocyclobutene (BCB).

An end portion of the additional organic protective layer AOL may overlap with the polarizing layer POL, the organic protective layer PVX, the first base BS1, the first barrier layer BR1, and the second base BS2. For example, as the mother substrate MS is cut, display devices DD may be separated from each other. This process defines the end portions of the additional organic protective layer AOL, the polarizing layer POL, the organic protective layer PVX, the first base BS1, the first barrier layer BR1, and the second base BS2.

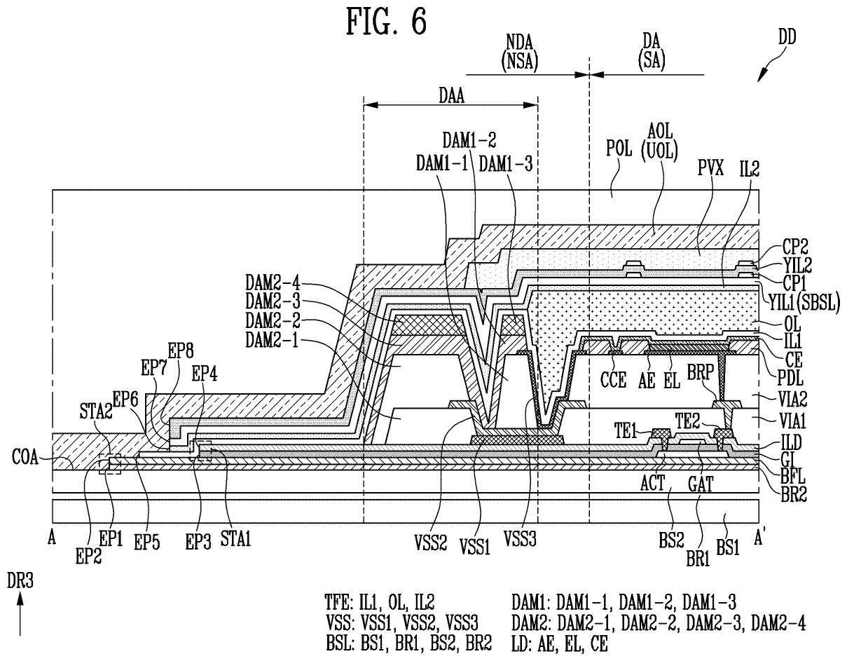

A display device DD according to a third embodiment will be described with reference to FIG. 6. Content overlapping with the above-described content will be briefly described or omitted.

The display device DD according to the third embodiment shown in FIG. 6 may be different from the display device DD according to the embodiment described with reference to FIG. 5 in that the additional organic protective layer AOL functions as the upper organic layer UOL.

In an embodiment, the additional organic protective layer AOL may contact at least a portion of the upper surface of the second base BS2 exposed by the second barrier layer BR2 and the buffer layer BFL in the organic contact area COA. The additional organic protective layer AOL and the second base BS2 may form a structure in which organic layers are continuously formed through the organic contact area COA. In the embodiment, as the organic contact area COA is formed, the risk of penetration of impurities such as moisture and the risk of delamination of inorganic layers may be reduced.

In an embodiment, referring to FIG. 6, the organic protective layer PVX may have an end portion in the dam area DAA. For example, the organic protective layer PVX may not extend to the organic contact area COA. The organic protective layer PVX may extend to the outside of the display device DD shorter than the gate insulating layer GI and the interlayer insulating layer GIL.

A method of manufacturing the display device DD according to an embodiment will be described with reference to FIGS. 7 to 26. Content overlapping with the above-described content will be briefly described or omitted.

First, a method of manufacturing the display device DD according to the first embodiment described above with reference to FIG. 4 will be described with reference to FIGS. 7 to 19.

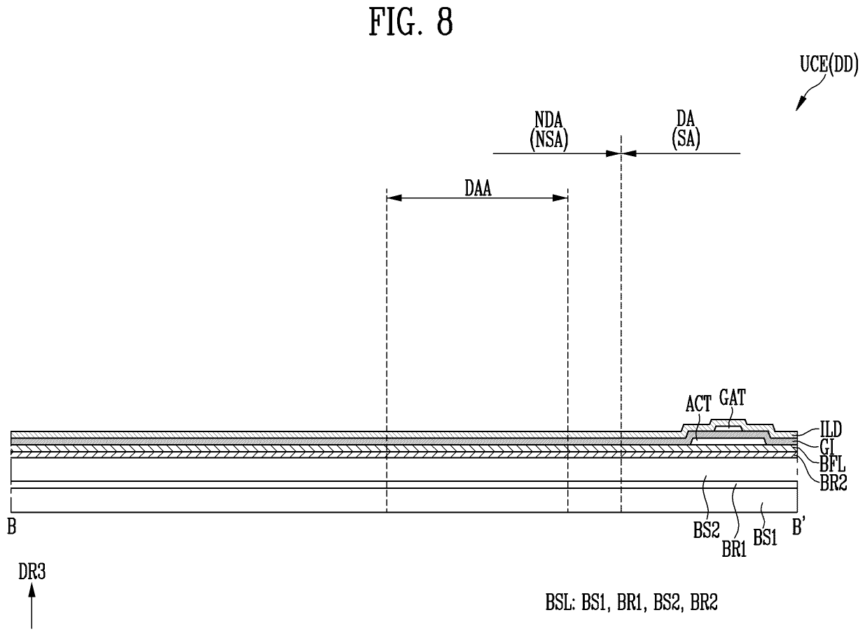

FIG. 7 is a plan view illustrating a structure in which a mother substrate includes unit cells to explain a method of manufacturing a display device according to an embodiment. FIGS. 8 to 19 are cross-sectional views schematically illustrating each process step of the method of manufacturing the display device according to an embodiment.

Referring to FIG. 7, the display device DD may be manufactured by using the mother substrate MS that includes unit cells UCE. A cutting process may be performed outside the dam area DAA of the mother substrate MS to separate the unit cells UCE, allowing the display device DD according to an embodiment to be provided. Each of the unit cells UCE separated by the cutting process may correspond to the display device DD according to an embodiment. For example, after a plurality of layers for manufacturing the display device DD are sequentially disposed on the mother substrate MS, the cutting process may be performed to provide an individually separated display device DD.

Hereinafter, with reference to FIGS. 8 to 19, a method of manufacturing the display device DD will be described based on a unit cell UCE and an area adjacent thereto. FIGS. 8 to 19 show a schematic cross-sectional structure taken along line B-B′ in FIG. 7. The process steps shown in FIGS. 8 to 19 may be understood as being applied to the entire mother substrate MS. For convenience of description, areas for forming the display device DD are schematically depicted in FIGS. 8 to 19.

Referring to FIG. 8, the base layer BSL may be provided. The buffer layer BFL, active layer ACT, gate insulating layer GI, gate conductive layer GAT, and interlayer insulating layer ILD may be sequentially disposed on the base layer BSL.

In an embodiment, a conductive layer or insulating layer on the base layer BSL may be formed based on a common process for manufacturing a semiconductor device. For example, the conductive layer or insulating layer on the base layer BSL may be formed by, but is not limited to, using a photolithography process, etched by various methods (such as wet etching, dry etching, or the like), and deposited by various methods (such as sputtering, chemical vapor deposition, or the like).

In this step, to provide the base layer BSL, a structure may be formed in which the first base BS1, the first barrier layer BR1, the second base BS2, and the second barrier layer BR2 are sequentially disposed.

In this step, the second base BS2 may be covered by the second barrier layer BR2, and the upper surface of the second base BS2 may not be exposed.

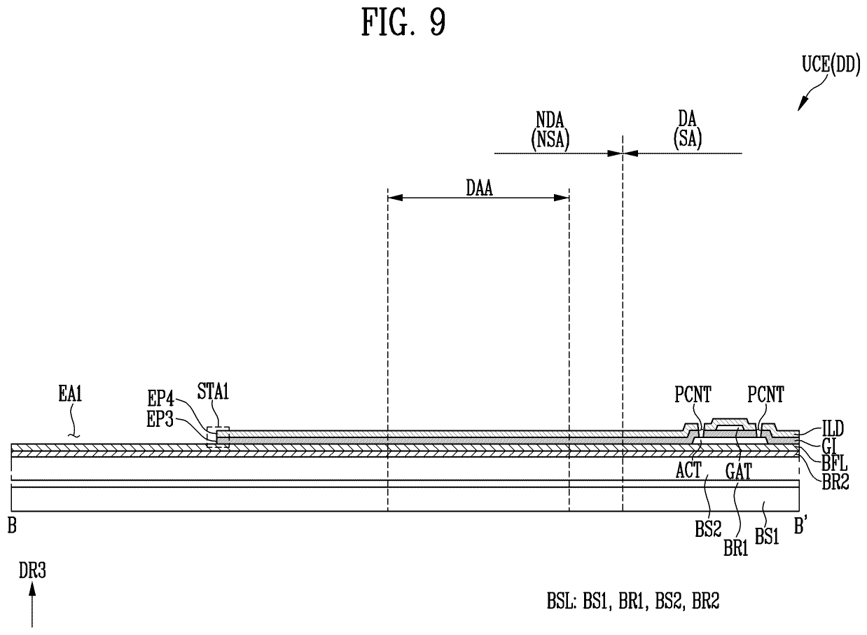

Referring to FIG. 9, at least portions of the gate insulating layer GI and the interlayer insulating layer ILD may be removed.

In this step, an etching process may be performed on the gate insulating layer GI and the interlayer insulating layer ILD using a first etch mask. For example, using the first etch mask, a first exposed area EA1 exposing a portion of the buffer layer BFL may be formed and a contact portion PCNT exposing the active layer ACT may be formed. For example, the process of exposing the buffer layer BFL and the etching process of exposing the active layer ACT may be performed using the same process.

In this step, the gate insulating end portion EP3 and the interlayer insulating end portion EP4, which are adjacent to the first exposed area EA1, may be formed, and the first step area STA1 may be defined.

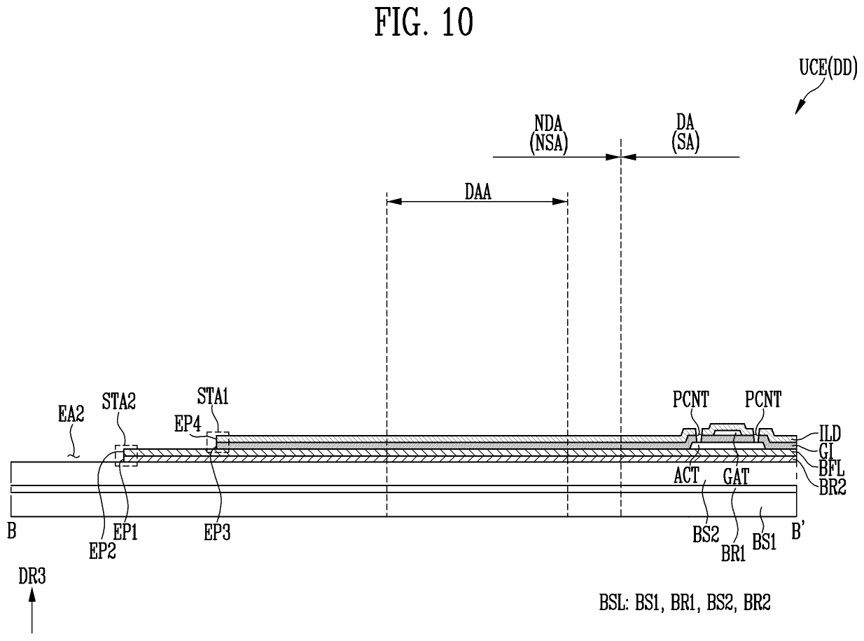

Referring to FIG. 10, at least portions of the second barrier layer BR2 and the buffer layer BFL may be removed.

In this step, an etching process may be performed on the second barrier layer BR2 and the buffer layer BFL using a second etch mask. For example, using the second etch mask, a second exposed area EA2 exposing a portion of the second base BS2 may be formed. The process of exposing the second base BS2 may be performed after the etching process on the gate insulating layer GI and the interlayer insulating layer ILD.

In this step, the barrier end portion EP1 and the buffer end portion EP2, which are adjacent to the second exposed area EA2, may be formed, and the second step area STA2 may be defined.

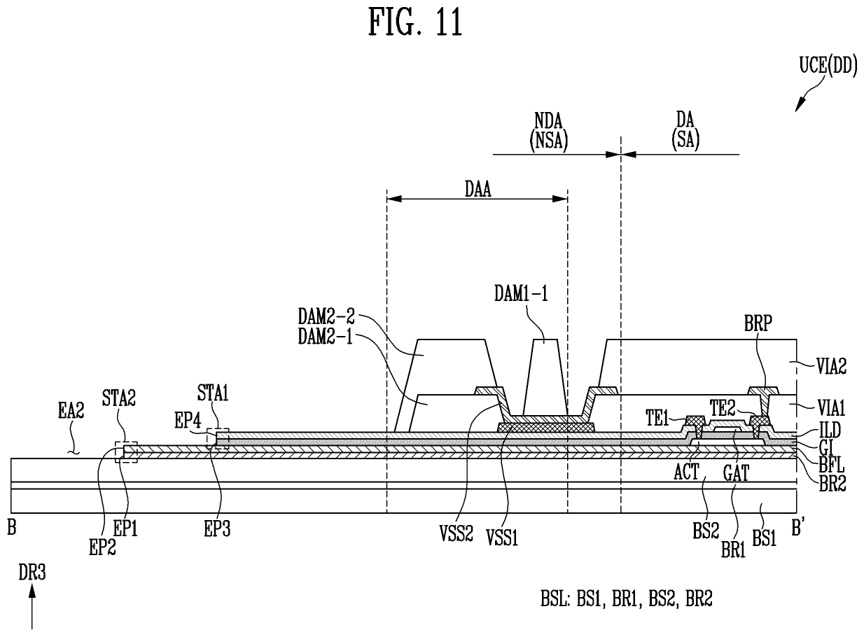

Referring to FIG. 11, the first and second transistor electrodes TE1 and TE2, the first cathode power source supply line VSS1, the first via layer VIA1, the (2-1)th dam DAM2-1, the bridge layer BRP, the second cathode power source supply line VSS2, the second via layer VIA2, the (1-1)th dam DAM1-1, and the (2-2)th dam DAM2-2 may be patterned (for example, sequentially patterned).

In this step, the second base BS2 may be maintained in an exposed state in the second exposed area EA2.

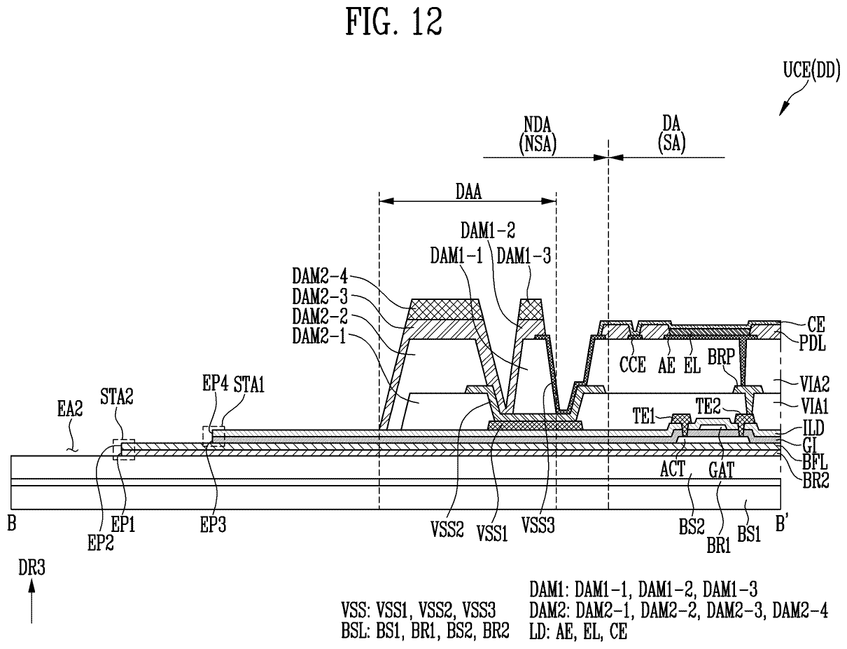

Referring to FIG. 12, the anode electrode AE, the cathode connection electrode CCE, the third cathode power source supply line VSS3, the pixel defining layer PDL, the (1-3)th dam DAM1-3, the (2-3)th Dam DAM2-3, the light emitting layer EL, the cathode electrode CE, the (1-3)th dam DAM1-3, and he (2-4)th dam DAM2-4 may be patterned (for example, sequentially patterned).

In this step, the second base BS2 may be maintained in an exposed state in the second exposed area EA2, and the first and second dams DAM1 and DAM2 and the light emitting element LD may be provided.

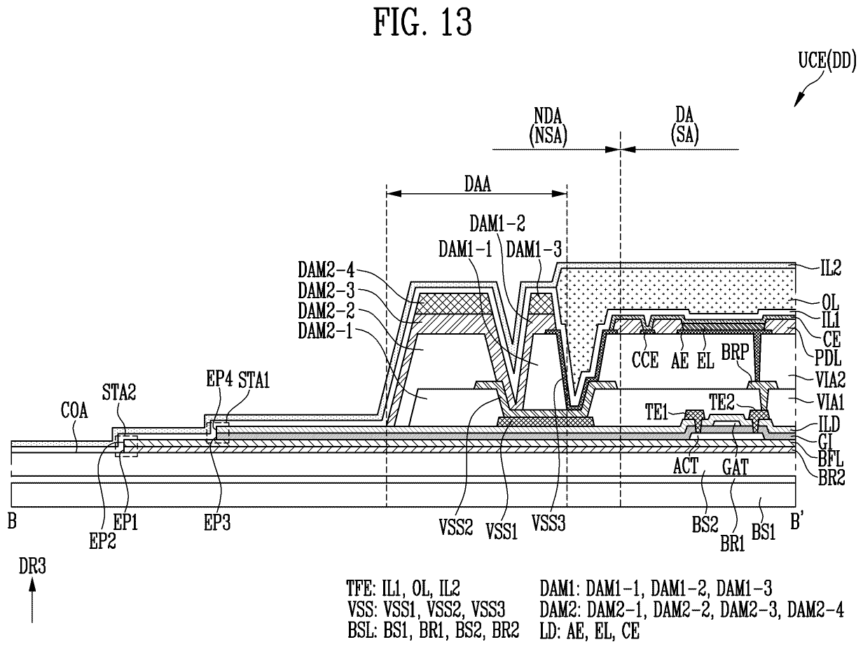

Referring to FIG. 13, the first inorganic insulating layer IL1, the organic encapsulation layer OL, and the second inorganic insulating layer IL2 may be disposed (for example, sequentially disposed), and the encapsulation layer TFE may be formed.

In this step, the first inorganic insulating layer IL1 may be formed to cover the barrier end portion EP1, the buffer end portion EP2, the gate insulating end portion EP3, and the interlayer insulating end portion EP4. The first inorganic insulating layer IL1 may cover the second exposed area EA2 and may contact the second base BS2.

In this step, the organic encapsulation layer OL may cover the light emitting element LD and may be formed inside the dam area DAA.

In this step, the second inorganic insulating layer IL2 may cover the organic encapsulation layer OL and an upper surface of the first inorganic insulating layer IL1 that is not covered by the organic encapsulation layer OL.

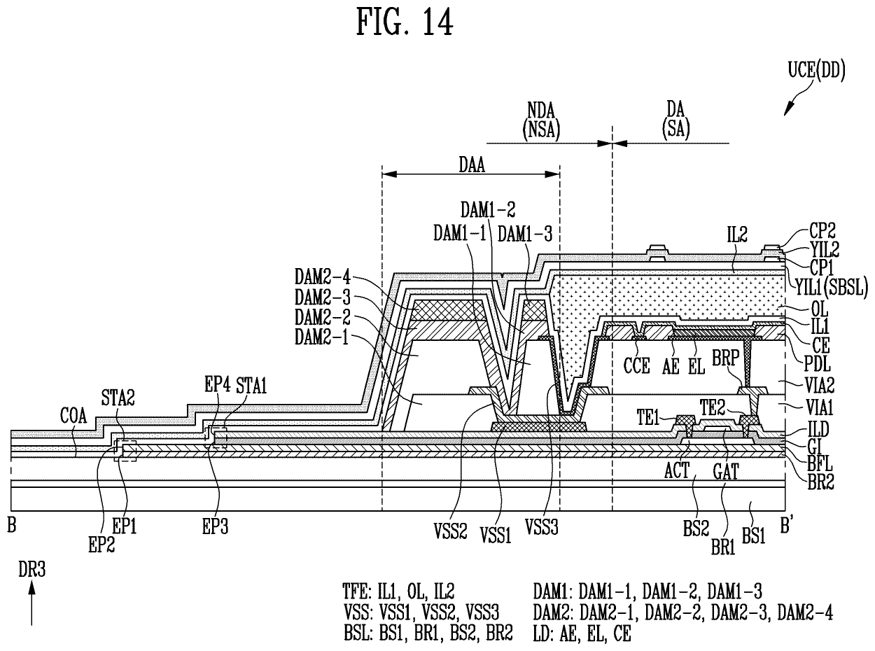

Referring to FIG. 14, the first upper insulating layer YIL1, the first conductive pattern layer CP1, the second upper insulating layer YIL2, and the second conductive pattern layer CP2 may be patterned (for example, sequentially patterned).

In this step, the first upper insulating layer YIL1 may cover the second inorganic insulating layer IL2. The second upper insulating layer YIL2 may cover the first conductive pattern layer CP1 and the first upper insulating layer YIL1. The first and second conductive pattern layers CP1 and CP2 are patterned to form sensing electrodes SP.

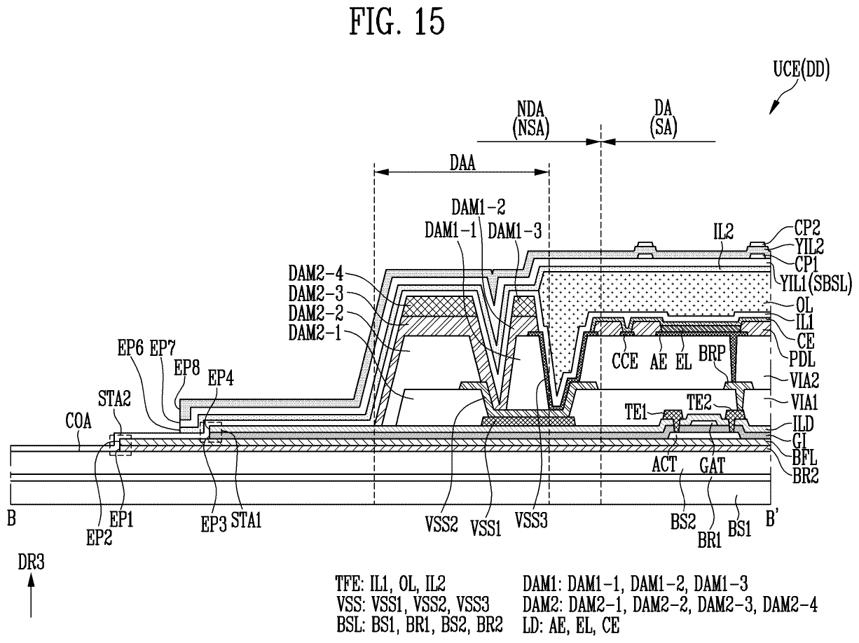

Referring to FIG. 15, at least portions of the second inorganic insulating layer IL2, the first upper insulating layer YIL1, and the second upper insulating layer YIL2 may be removed.

In this step, an etching process may be performed on the second inorganic insulating layer IL2, the first upper insulating layer YIL1, and the second upper insulating layer YIL2 using a third etch mask.

In this step, the second inorganic insulating end portion EP6, the first upper insulating end portion EP7, and the second upper insulating end portion EP8 may be formed between the first step area STA1 and the second step area STA2.

In this step, the first inorganic insulating layer IL1 may not be removed. Accordingly, a portion of the second base BS2 may still contact the first inorganic insulating layer IL1.

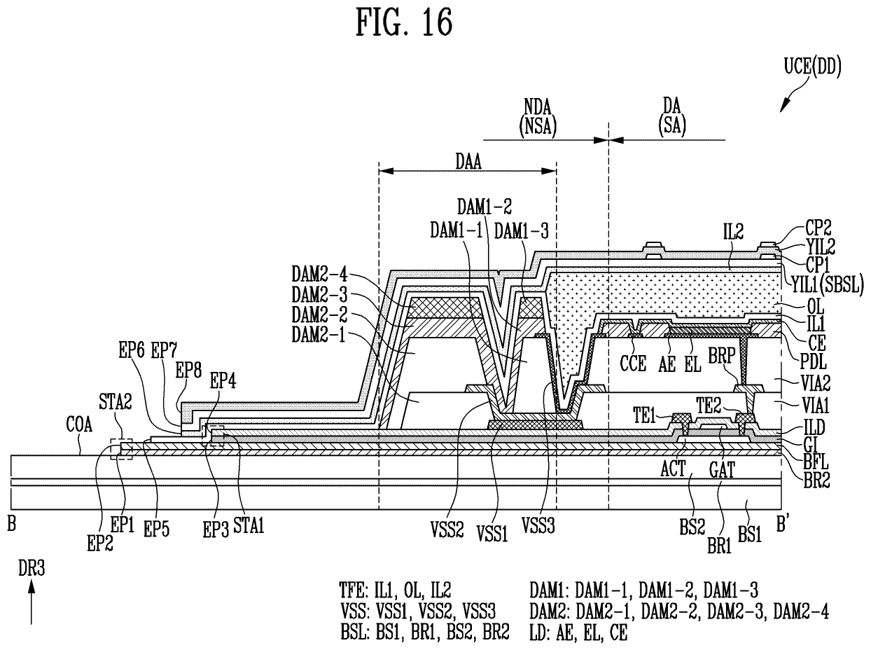

Referring to FIG. 16, at least a portion of the first inorganic insulating layer IL1 may be removed.

In this step, an etching process may be performed on the first inorganic insulating layer IL1 using a fourth etch mask.

In this step, the first inorganic insulating end portion EP5 may be formed between the first step area STA1 and the second step area STA2.

In this step, a portion of the first inorganic insulating layer IL1 contacting the second base BS2 may be removed, the barrier end portion EP1 and the buffer end portion EP2 may be exposed, and at least a portion of the second base BS2 may be exposed.

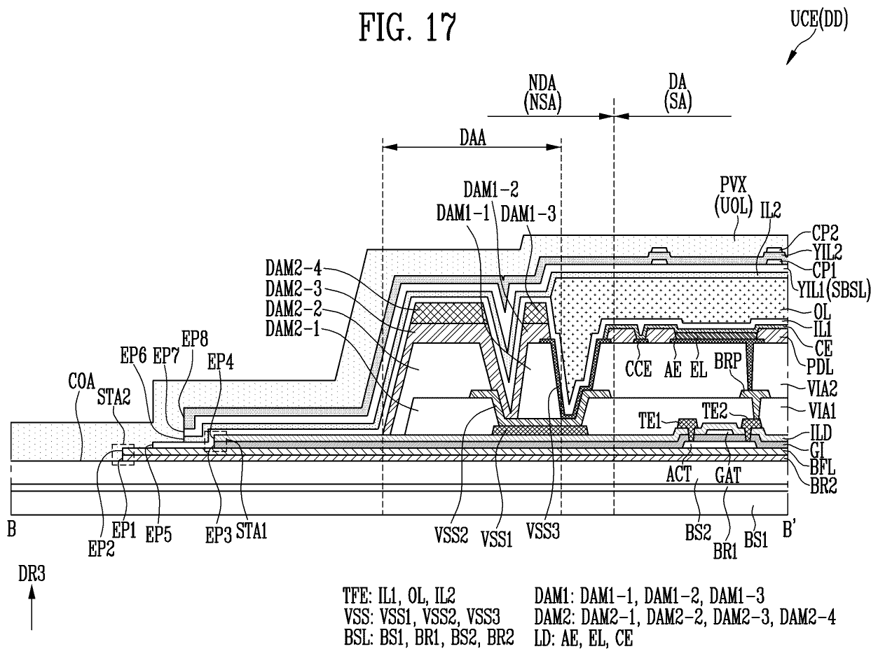

Referring to FIG. 17, the organic protective layer PVX that functions as the upper organic layer UOL may be formed.

In this step, the organic protective layer PVX may cover the barrier end portion EP1, the buffer end portion EP2, the first inorganic insulating end portion EP5, the second inorganic insulating end portion EP6, the first upper insulating end portion EP7, and the second upper insulating end portion EP8.

In this step, the organic protective layer PVX may contact the exposed upper surface of the second base BS2, and the organic contact area COA may be defined.

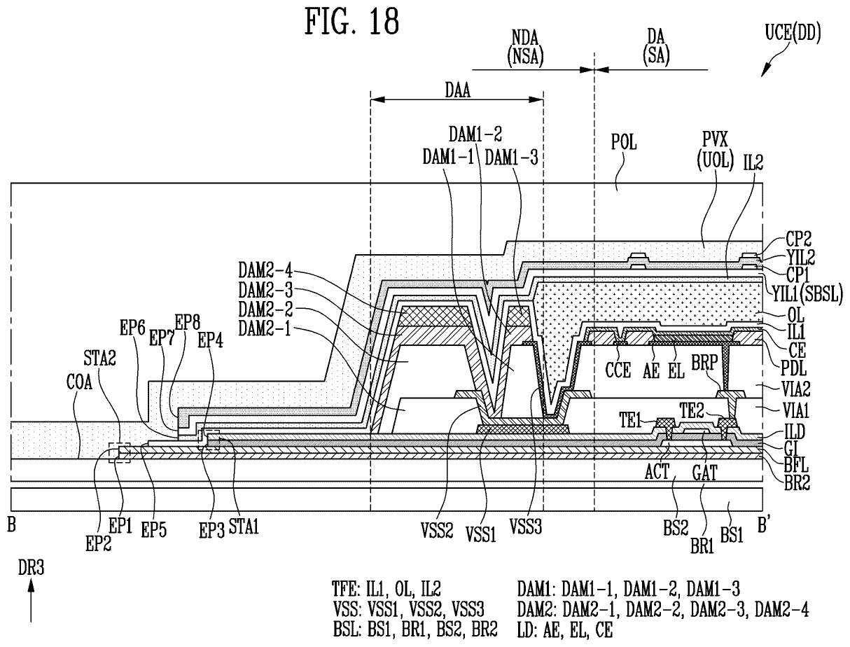

Referring to FIG. 18, the polarizing layer POL may be formed.

In this step, the polarizing layer POL may cover the organic protective layer PVX that functions as the upper organic layer UOL. Referring to FIG. 7, in this step, the polarizing layer POL may be disposed over the unit cells UCE and formed across the entire mother substrate MS.

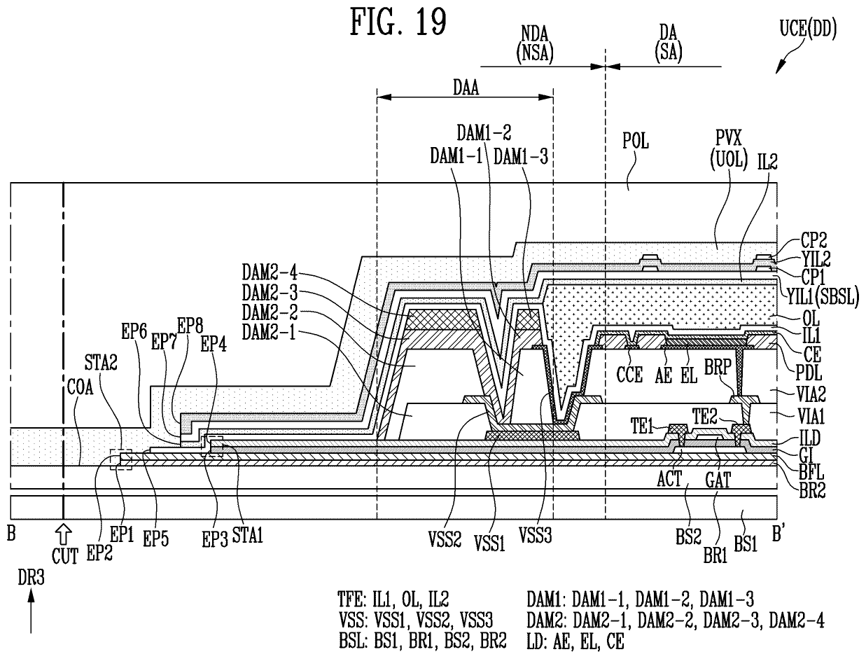

Referring to FIG. 19, the cutting process may be performed to separate the unit cells UCE. The cutting process may be applied outside the dam area DAA in each of the unit cells UCE.

The cutting process performed in this step may include a laser application process. In an embodiment, the cutting process may be referred to as a laser process or a scribing process. For convenience of description, a cutting line where the cutting process is applied is indicated in this specification as a one-dot chain line.

In this step, the cutting line where the cutting process is performed may be defined in the organic contact area COA. As described above, defining the cutting line in a structure with continuously formed organic layers may reduce the risk of impurities, such as moisture, and the risk of delamination of inorganic layers. For example, in this step, stress may be generated in the polarizing layer POL in a direction from the non-display area NDA towards the display area DA. However, the formation of the organic contact area COA may reduce the risk of delamination of the inorganic layers.

As this step is performed, the unit cells UCE may be separated from each other, and the display device DD according to the embodiment may be provided.

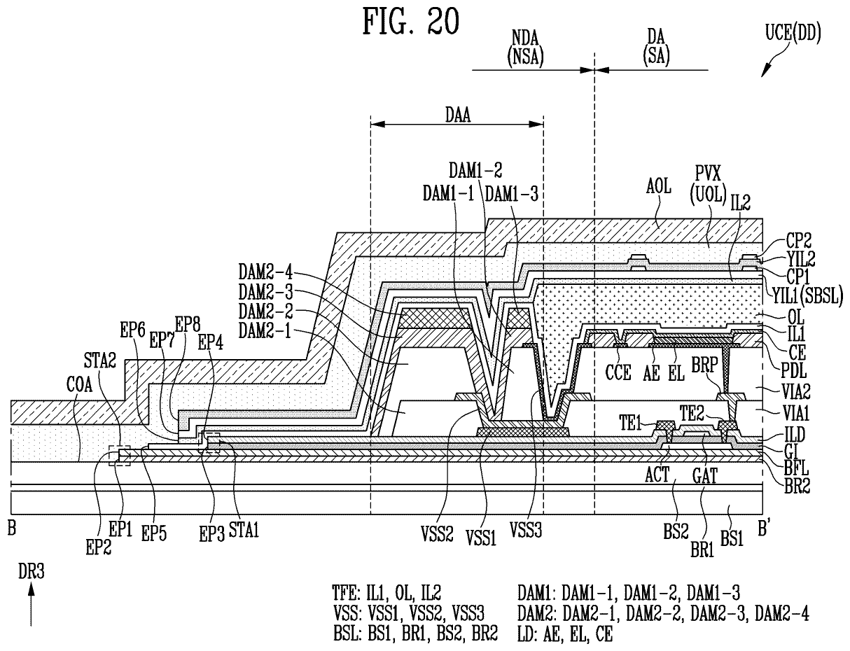

A method of manufacturing the display device DD according to the second embodiment described with reference FIG. 5 will be described with reference to FIGS. 20 to 22 along with FIG. 7. Content overlapping with the above-described content will be briefly described or omitted.

FIGS. 20 to 22 are cross-sectional views schematically illustrating each process step of a method of manufacturing of the display device according to an embodiment. FIGS. 20 to 22 show a schematic cross-sectional structure taken along line B-B′ in FIG. 7, similar to FIGS. 8 to 19 described above.

In a method of manufacturing the display device DD according to the embodiment, process steps described above with reference to FIGS. 8 to 17 may be performed in the same manner.

Referring to FIG. 20, after the organic protective layer PVX is formed, the additional organic protective layer AOL may be formed.

In this step, the additional organic protective layer AOL may be disposed to cover an upper surface of the organic protective layer PVX. The additional organic protective layer AOL may overlap the organic contact area COA in a plan view.

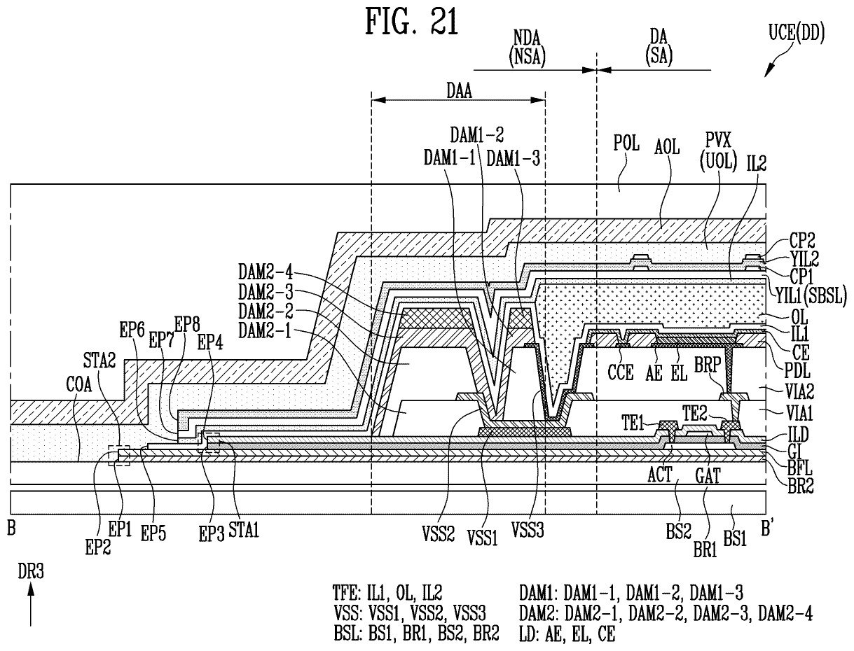

Referring to FIG. 21, the polarizing layer POL may be formed on the additional organic protective layer AOL.

In this step, the polarizing layer POL may entirely cover an upper surface of the additional organic protective layer AOL. Referring to FIG. 7, the polarizing layer POL and the additional organic protective layer AOL may contact each other throughout the mother substrate MS.

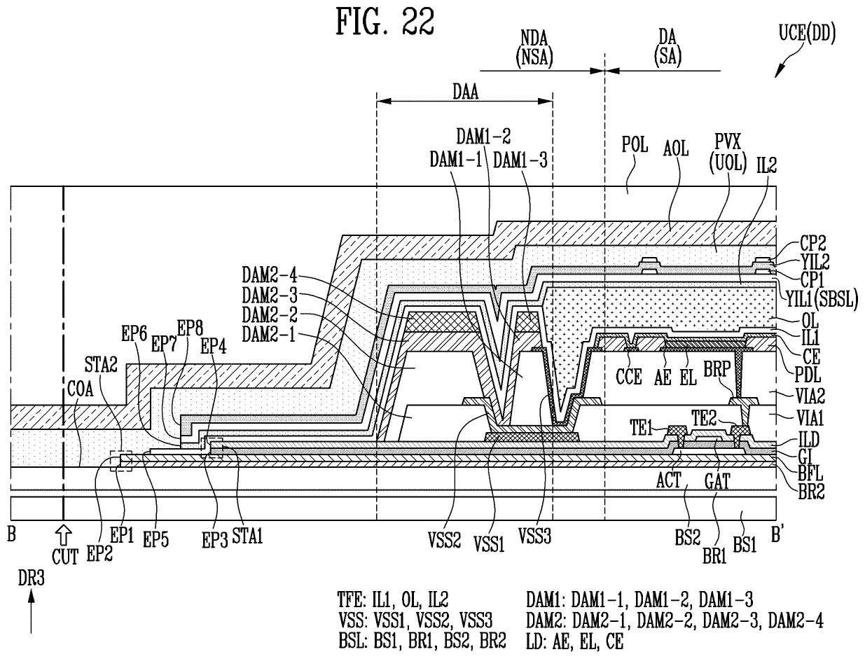

Referring to FIG. 22, the cutting process may be performed to separate the unit cells UCE.

In this step, the cutting process may be performed to correspond to the organic contact area COA. In an embodiment, the additional organic protective layer AOL may be further cut. Accordingly, the display device DD separated from the mother substrate MS may be provided.

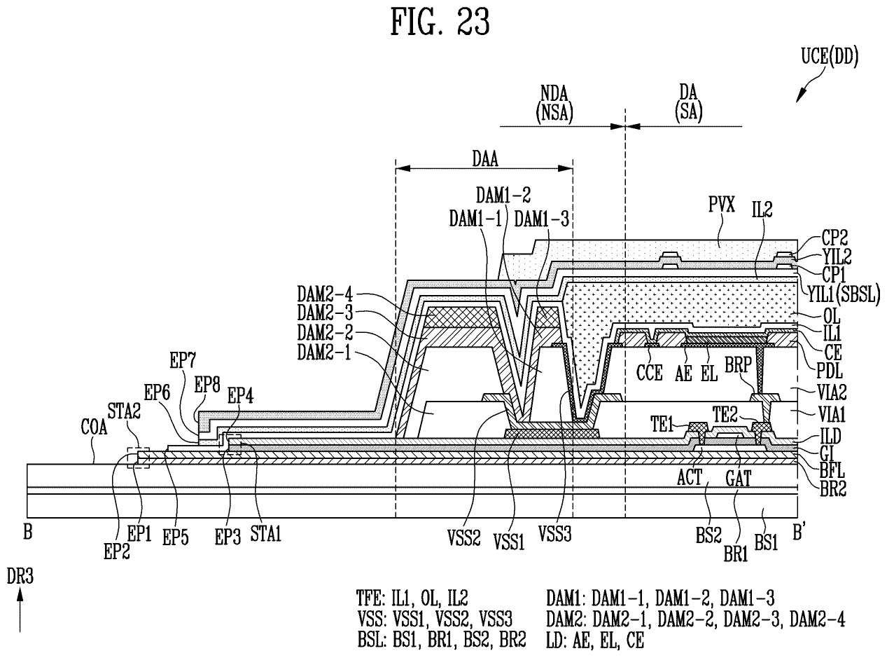

A method of manufacturing the display device DD according to the third embodiment described with reference to FIG. 6 will be described with reference to FIGS. 23 to 26 along with FIG. 7. Content overlapping with the above-described content will be briefly described or omitted.

FIGS. 23 to 26 are cross-sectional views schematically illustrating each process step of a method of manufacturing of the display device according to an embodiment. FIGS. 23 to 26 show a schematic cross-sectional structure taken along line B-B′ in FIG. 7, similar to FIGS. 8 to 19 described above.

In a method of manufacturing the display device DD according to the embodiment, process steps described above with reference to FIGS. 8 to 16 may be performed in the same manner.

Referring to FIG. 23, after a portion of the second base BS2 is exposed, the organic protective layer PVX may be patterned in some areas so as not to contact the second base BS2.

In this step, the organic protective layer PVX may not function as the upper organic layer UOL, and may be partially disposed in some areas including the display area DA to be spaced apart from the organic contact area COA.

In this step, the second base BS2 may still be exposed and the barrier end portion EP1, the buffer end portion EP2, the first inorganic insulating end portion EP5, the second inorganic insulating end portion EP6, the first upper insulating end portion EP7, and the second upper insulating end portion EP8 may also still be exposed.

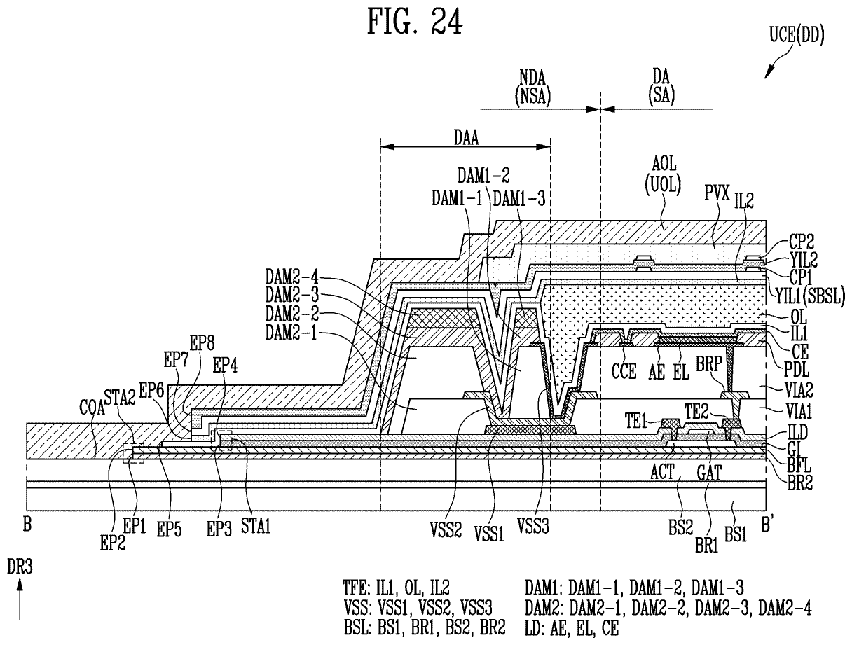

Referring to FIG. 24, after the organic protective layer PVX is formed, the additional organic protective layer AOL may be formed.

The additional organic protective layer AOL may function as the upper organic layer UOL in the embodiment. For example, in this step, the additional organic protective layer AOL may contact the second base BS2 in the organic contact area COA.

In this step, the additional organic protective layer AOL may cover the barrier end portion EP1, the buffer end portion EP2, the first inorganic insulating end portion EP5, the second inorganic insulating end portion EP6, the first upper insulating end portion EP7, and the second upper insulating end portion EP8.

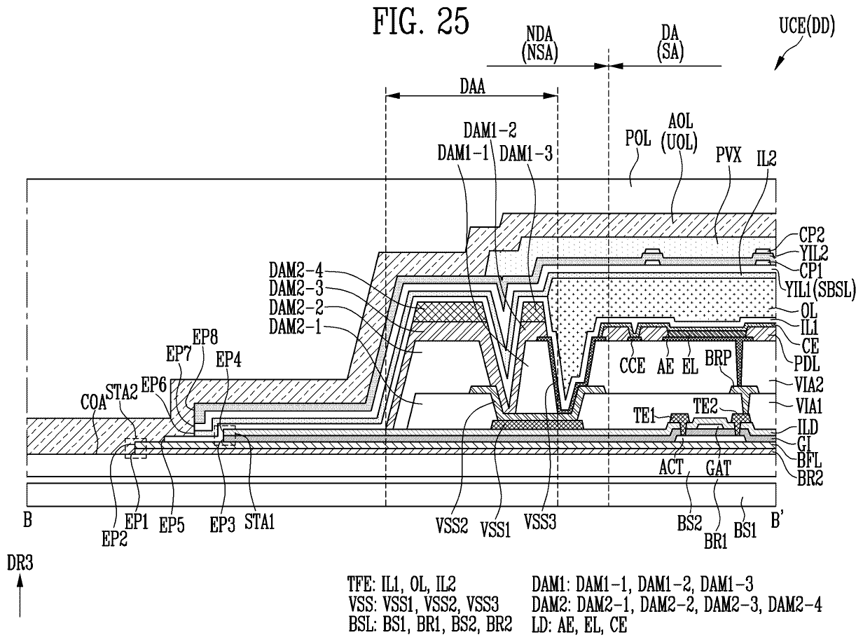

Referring to FIG. 25, the polarizing layer POL may be formed on the additional organic protective layer AOL.

In this step, the polarizing layer POL may entirely cover the upper surface of the additional organic protective layer AOL. Referring to FIG. 7, the polarizing layer POL and the additional organic protective layer AOL may contact each other throughout the mother substrate MS.

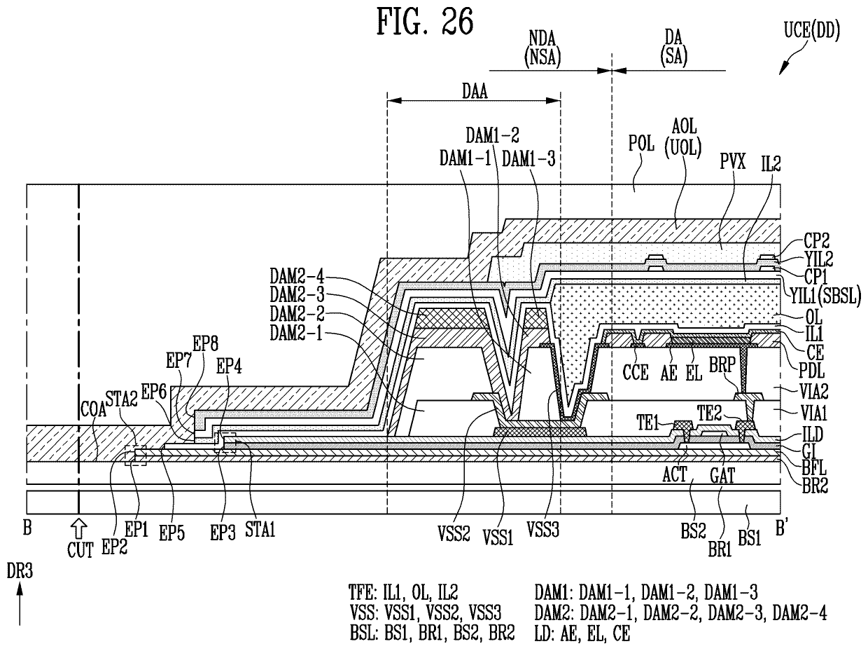

Referring to FIG. 26, the cutting process may be performed to separate the unit cells UCE.

In this step, the cutting process may be performed to correspond to the organic contact area COA. Unlike the process according to the above-described embodiment, the cutting process may not be applied to the organic protective layer PVX, and the cutting process may be applied to layers including the additional organic protective layer AOL. Accordingly, the display device DD separated from the mother substrate MS may be provided.

According to the embodiments of the disclosure, a display device having robust characteristics against the external environment, and a method of manufacturing the display device, may be provided.

According to the embodiments of the disclosure, a display device in which the risk of moisture penetration and stress may be reduced, and a method of manufacturing the display device, may be provided.

According to the embodiments of the disclosure, a display device in which the risk of delamination of inorganic layers may be reduced, and a method of manufacturing the display device, may be provided.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device including a display area and a non-display area, comprising:
a base layer including:
a first base,
a first barrier layer on the first base,
a second base on the first barrier layer, and
a second barrier layer on the second base;
a light emitting element disposed on the base layer in the display area; and
an upper organic layer disposed over the display area and the non-display area, wherein
each of the first base and the second base includes an organic material,
each of the first barrier layer and the second barrier layer includes an inorganic material,
the non-display area includes an organic contact area, and the second barrier layer exposes the second base in the organic contact area, and
the upper organic layer and the second base contact each other in the organic contact area.

2. The display device of claim 1, further comprising:
a buffer layer disposed on the second barrier layer, extending over the display area and the non-display area;
an active layer disposed on the buffer layer in the display area;
a gate insulating layer disposed on the buffer layer, extending over the display area and the non-display area, and covering the active layer;
a gate conductive layer including at least a portion disposed on the gate insulating layer in the display area;
an interlayer insulating layer disposed on the gate insulating layer, extending over the display area and the non-display area, and covering the gate conductive layer; and
a first inorganic insulating layer extending over the display area and the non-display area and covering the light emitting element, wherein
the second barrier layer includes a barrier end portion in the non-display area,
the buffer layer includes a buffer end portion in the non-display area,
the gate insulating layer includes a gate insulating end portion in the non-display area,
the interlayer insulating layer includes an interlayer insulating end portion in the non-display area, and
the first inorganic insulating layer includes a first inorganic insulating end portion in the non-display area.

3. The display device of claim 2, wherein
the buffer layer and the active layer contact each other, and
the buffer layer exposes the second base in the non-display area and does not expose the second base in the display area.

4. The display device of claim 2, wherein
the first inorganic insulating end portion is disposed between the buffer end portion and the interlayer insulating end portion,
the first inorganic insulating layer covers a portion of an upper surface of the buffer layer and exposes another portion of the upper surface of the buffer layer in a portion of the non-display area, and
the upper organic layer and the buffer layer contact each other at the portion of the upper surface of the buffer layer exposed by the first inorganic insulating layer.

5. The display device of claim 2, wherein the barrier end portion and the buffer end portion are directly adjacent to the organic contact area.

6. The display device of claim 5, wherein the barrier end portion and the buffer end portion overlap each other in a plan view.

7. The display device of claim 2, wherein the gate insulating end portion and the interlayer insulating end portion are covered by the first inorganic insulating layer.

8. The display device of claim 7, wherein the gate insulating end portion and the interlayer insulating end portion overlap each other in a plan view.

9. The display device of claim 2, further comprising:
a dam disposed in a dam area formed in the non-display area;
an organic encapsulation layer including at least a portion disposed on the first inorganic insulating layer in an area surrounded by the dam;
a second inorganic insulating layer covering the organic encapsulation layer and disposed on the first inorganic insulating layer;
a first upper insulating layer disposed on the second inorganic insulating layer;
a first conductive pattern layer disposed on the first upper insulating layer;
a second upper insulating layer covering the first conductive pattern layer and disposed on the first upper insulating layer; and
a second conductive pattern layer disposed on the second upper insulating layer, wherein
the second inorganic insulating layer includes a second inorganic insulating end portion in the non-display area,
the first upper insulating layer includes a first upper insulating end portion in the non- display area, and
the second upper insulating layer includes a second upper insulating end portion in the non-display area.

10. The display device of claim 9, wherein
the organic contact area is formed outside the dam area, and
the first conductive pattern layer and the second conductive pattern layer form sensing electrodes that obtains information about a user's touch input.

11. The display device of claim 9, wherein the second inorganic insulating end portion, the first upper insulating end portion, and the second upper insulating end portion overlap each other in a plan view.

12. The display device of claim 9, wherein the upper organic layer covers the second conductive pattern layer, the barrier end portion, the buffer end portion, the first inorganic insulating end portion, the second inorganic insulating end portion, the first upper insulating end portion, and the second upper insulating end portion, and is spaced apart from the gate insulating end portion and the interlayer insulating end portion.

13. The display device of claim 1, further comprising:
a polarizing layer disposed on the upper organic layer, wherein
the polarizing layer, the upper organic layer, the first base, the first barrier layer, and the second base have end portions that overlap each other.

14. The display device of claim 9, further comprising:
an organic protective layer disposed on the second conductive pattern layer and spaced apart from the organic contact area; and
a polarizing layer disposed on the upper organic layer, wherein
the upper organic layer covers the organic protective layer.

15. A method of manufacturing a display device including a non-display area and a display area, comprising:
providing a base layer including a first base, a first barrier layer on the first base, a second base on the first barrier layer, and a second barrier layer on the second base;
disposing a buffer layer on the second barrier layer;
disposing a gate insulating layer on the buffer layer;
disposing an interlayer insulating layer on the gate insulating layer;
exposing the buffer layer in a first exposed area which is a portion of the non-display area by removing at least portions of the gate insulating layer and the interlayer insulating layer;
exposing the second base in a second exposed area which is a portion of the non- display area by removing at least portions of the second barrier layer and the buffer layer;
forming a light emitting element on the base layer in the display area;
forming a first inorganic insulating layer, at least a portion of which covers the light emitting element;
forming an organic encapsulation layer on the first inorganic insulating layer;
forming a second inorganic insulating layer on the organic encapsulation layer;
forming a first upper insulating layer on the second inorganic insulating layer;
forming a second upper insulating layer on the first upper insulating layer;
exposing the first inorganic insulating layer by removing at least portions of the second inorganic insulating layer, the first upper insulating layer, and the second upper insulating layer;
exposing the second base by removing at least a portion of the first inorganic insulating layer; and
forming an upper organic layer over the display area and the non-display area, wherein
the forming of the upper organic layer includes contacting the upper organic layer and the second base in an organic contact area.

16. The method of claim 15, further comprising:
performing a cutting process based on a cutting line defined in the organic contact area.

17. The method of claim 15, further comprising:
patterning an active layer on the buffer layer, wherein
the exposing of the buffer layer includes forming a contact portion exposing the active layer.

18. The method of claim 15, wherein
the exposing of the buffer layer includes forming a first step area defined by end portions of the gate insulating layer and the interlayer insulating layer,
the exposing of the second base in the second exposed area which is a portion of the non-display area by removing at least portions of the second barrier layer and the buffer layer includes forming a second step area defined by end portions of the second barrier layer and the buffer layer, and
the exposing of the second base by removing at least a portion of the first inorganic insulating layer includes forming an end portion of the first inorganic insulating layer between the first step area and the second step area.

19. The method of claim 15, wherein
the exposing of the second base in the second exposed area which is a portion of the non-display area by removing at least portions of the second barrier layer and the buffer layer includes etching the second barrier layer and the buffer layer using a first etch mask, and
the exposing of the first inorganic insulating layer includes etching the second inorganic insulating layer, the first upper insulating layer, and the second upper insulating layer using a second etch mask.

20. The method of claim 15, further comprising:
disposing a polarizing layer on the upper organic layer.
